(19) United States
(12) Patent Application Publication
(10) Pub. No.: US 2026/0150522 A1
(43) Pub. Date: May 28, 2026

(54) DISPLAY DEVICE, METHOD OF MANUFACTURING DISPLAY DEVICE, AND ELECTRONIC APPARATUS USING DISPLAY DEVICE

(71) Applicant: Sony Semiconductor Solutions Corporation, Kanagawa (JP)

(72) Inventors: Daisuke Hamashita, Kanagawa (JP); Kenichi Aoyagi, Kanagawa (JP); Kenta Hasegawa, Atsugi (JP); Atsushi Yamamoto, Kanagawa (JP); Takashi Sakairi, Kanagawa (JP)

(21) Appl. No.: 19/447,536

(22) Filed: Jan. 13, 2026

Related U.S. Application Data
(63) Continuation of application No. 18/016,738.

(30) Foreign Application Priority Data
Aug. 12, 2020 (JP) 2020-136364

(51) Int. Cl. H10K 59/122; H10K 59/12; H10K 59/80

(52) U.S. Cl. CPC H10K 59/122; H10K 59/1201; H10K 59/873; H10K 59/8791; H10K 59/8792; H10K 59/80521

(57) ABSTRACT

Display devices that curb light leakage between adjacent pixels are disclosed. In one example, a display device comprises an anode electrode, a cathode electrode, an organic layer between the anode electrode and the cathode electrode, a first insulating layer covering at least a portion of a side surface of the anode electrode and at least a portion of a top surface of the anode electrode, and a cavity between the anode electrode and another anode electrode adjacent to the anode electrode. A first distance between an uppermost point and a lowermost point of a first side surface of the first insulating layer facing the cavity is shorter than a second distance between an uppermost point and a lowermost point of the cavity in a cross-sectional view.

### CROSS REFERENCE TO RELATED APPLICATIONS

This Application is a Continuation Application of U.S. application Ser. No. 18/016,738, filed Jan. 18, 2023, which is a national stage of PCT/JP 2021/029374, filed Aug. 6, 2021, which claims the benefit of Japanese Patent Application JP 2020-136364 filed on Aug. 12, 2020, the contents of which are incorporated herein by reference in their entirety.

### TECHNICAL FIELD

The present disclosure relates to a display device, a method of manufacturing the display device, and an electronic apparatus using the display device. Particularly, the present disclosure relates to a display device including light-emitting elements having an organic layer, a method of manufacturing the display device, and an electronic apparatus using the display device.

### BACKGROUND ART

In a display device in which a plurality of light-emitting elements each having an organic layer serving as a light-emitting layer and an electrode are formed, it is desired to curb light leakage between adjacent pixels.

The technology of PTL 1 discloses a display device including a plurality of light-emitting elements and a protective layer for protecting the plurality of light-emitting elements. In this display device, the light-emitting elements include a plurality of lower electrodes separated by insulating parts, an organic layer disposed on the lower electrodes, and an upper electrode covering the organic layer. Further, an isolation part having a refractive index different from that of the protective layer is provided in a portion corresponding to the upper side of an area between adjacent lower electrodes.

### CITATION LIST

### Patent Literature

### [PTL 1]

JP 2018-92873A

### SUMMARY

### Technical Problem

The technology of PTL 1 needs to be further improved in terms of curbing light leakage between adjacent pixels.

The present disclosure has been made in view of the aforementioned circumstances, and an object of the present disclosure is to provide a display device capable of curbing light leakage between adjacent pixels, a method of manufacturing the display device, and an electronic apparatus using the display device.

### Solution to Problem

For example, the present disclosure is (1) a display device including a plurality of light-emitting elements in which a lower electrode, an organic layer and an upper electrode are laminated in this order on a substrate,
an upper surface protective layer laminated on an upper surface side of the light-emitting elements and covering the upper electrode, and
an element isolation wall disposed between adjacent light-emitting elements and covering side edge surfaces of the light-emitting elements,
wherein
the element isolation wall extends from the light-emitting elements toward the upper surface protective layer in a thickness direction of the light-emitting elements.

The present disclosure may be (2) the display device according to (1),
wherein a low refractive index portion having a refractive index lower than a refractive index of the element isolation wall is formed in the element isolation wall.

The present disclosure may be (3) the display device according to (1),
wherein the upper electrode is first upper electrodes isolated from each other and facing the organic layer,
a second upper electrode connecting adjacent first upper electrodes is provided, and
the second upper electrode is disposed along the surface of the element isolation wall.

For example, the present disclosure is (4) a method of manufacturing a display device, including a process of forming a first laminate in which a lower electrode, an organic layer, a first upper electrode, and an upper surface protective layer are laminated in this order on a substrate,
a process of forming a first groove to a predetermined depth from the upper surface protective layer at a predetermined position in the first laminate,
a process of forming a second laminate by forming an element isolation wall in the first groove,
a process of forming a second groove from the upper surface protective layer to a position of the first upper electrode in a predetermined region around the element isolation wall in the second laminate, and
a process of forming a second upper electrode in the second groove.

For example, the present disclosure is (5) a method of manufacturing a display device, including a process of forming a first laminate in which a laminate obtained by laminating a lower electrode, an organic layer, a first upper electrode, and an upper surface protective layer in this order and an assistance layer are provided on a substrate,
a process of forming a first groove to a predetermined depth at a position determined according to a pattern of pixels in the first laminate through etching processing, and forming a sidewall protective film having the assistance layer as a base end along an inner wall of the first groove with the etching processing,
a process of forming a second laminate by forming an element isolation wall in the first groove,
a process of forming a second groove from the upper surface protective layer to a position of the first upper electrode in a predetermined region around the element isolation wall in the second laminate, and
a process of forming a second upper electrode in the second groove.

The present disclosure may be (6) an electronic apparatus including the display device according to (1).

### BRIEF DESCRIPTION OF DRAWINGS

FIG. 1 is a cross-sectional view showing a schematic configuration of an embodiment of a display device according to a first embodiment.

FIG. 2A is a cross-sectional view showing a state of a cross section taken along line A-A in FIG. 1.

FIG. 2B is a cross-sectional view showing a state of a cross section taken along line B-B in FIG. 1.

FIG. 2C is a cross-sectional view showing a state of a cross section taken along line C-C in FIG. 1.

FIG. 2D is a cross-sectional view showing a state of a cross section taken along line D-D in FIG. 1.

FIG. 2E is a cross-sectional view showing a state of a cross section taken along line E-E in FIG. 1.

FIG. 3A is a cross-sectional view corresponding to a state of the cross section taken along line A-A in FIG. 1 in one modified example of the display device according to the first embodiment.

FIG. 3B is a cross-sectional view corresponding to a state of the cross section taken along line B-B in FIG. 1 in one modified example of the display device according to the first embodiment.

FIG. 3C is a cross-sectional view corresponding to a state of the cross section taken along line C-C in FIG. 1 in one modified example of the display device according to the first embodiment.

FIG. 3D is a cross-sectional view corresponding to a state of the cross section taken along line D-D in FIG. 1 in one modified example of the display device according to the first embodiment.

FIG. 3E is a cross-sectional view corresponding to a state of the cross section taken along line E-E in FIG. 1 in one modified example of the display device according to the first embodiment.

FIG. 4A is a cross-sectional view showing a schematic configuration of an embodiment of a display device according to a second embodiment.

FIG. 4B is a cross-sectional view showing a state of a cross section taken along line IVB-IVB in FIG. 4A.

FIG. 5A is a diagram showing a state of a cross section taken along line V-V in FIG. 4A for describing an example of a sub-pixel layout. FIG. 5B and FIG. 5C are diagrams for describing other sub-pixel layout examples.

FIG. 6A is a cross-sectional view showing a schematic configuration of a modified example of the display device according to the second embodiment.

FIG. 6B is a cross-sectional view showing a schematic configuration of a modified example of the display device according to the second embodiment.

FIG. 7 is a cross-sectional view showing a schematic configuration of a modified example of the display device according to the second embodiment.

FIG. 8A and FIG. 8B are plan views for describing a modified example of the display device according to the second embodiment.

FIG. 9A, FIG. 9B, FIG. 9C, and FIG. 9D are diagrams for describing a method of manufacturing the display device according to the second embodiment.

FIG. 10A, FIG. 10B, FIG. 10C, and FIG. 10D are diagrams for describing a method of manufacturing the display device according to the second embodiment.

FIG. 11 is a cross-sectional view showing a schematic configuration of an embodiment of a display device according to a third embodiment.

FIG. 12A, FIG. 12B, FIG. 12C, and FIG. 12D are diagrams for describing a method of manufacturing the display device according to the third embodiment.

FIG. 13A and FIG. 13B are cross-sectional views showing a schematic configuration of a modified example of the display device according to the third embodiment.

FIG. 14A and FIG. 14B are cross-sectional views showing a schematic configuration of a modified example of the display device according to the third embodiment.

FIG. 15A, FIG. 15B, FIG. 15C, and FIG. 15D are diagrams for describing a method of manufacturing a modified example of the display device according to the third embodiment.

FIG. 16A and FIG. 16B are cross-sectional views showing a schematic configuration of a modified example of the display device according to the third embodiment.

FIG. 17A is a cross-sectional view showing a schematic configuration of an embodiment of a display device according to a fourth embodiment. FIG. 17B is a plan view showing the schematic configuration of the embodiment of the display device according to the fourth embodiment.

FIG. 18A and FIG. 18B are cross-sectional views showing a schematic configuration of an embodiment of the display device according to the fourth embodiment.

FIG. 19A and FIG. 19B are cross-sectional views showing a schematic configuration of a modified example of the display device according to the fourth embodiment.

FIG. 20 is a cross-sectional view showing a schematic configuration of a modified example of the display device according to the fourth embodiment.

FIG. 21A and FIG. 21B are cross-sectional views showing a schematic configuration of a modified example of the display device according to the fourth embodiment.

FIG. 22A, FIG. 22B, and FIG. 22C are diagrams for describing a modified example of the display device according to the fourth embodiment.

FIG. 23A, FIG. 23B, and FIG. 23C are diagrams for describing a method of manufacturing the display device according to the fourth embodiment.

FIG. 24A and FIG. 24B are diagrams for describing the method of manufacturing the display device according to the fourth embodiment.

FIG. 25A and FIG. 25B are diagrams for describing an embodiment of an electronic apparatus using a display device.

FIG. 26 is a diagram for describing an embodiment of an electronic apparatus using a display device.

FIG. 27 is a diagram for describing an embodiment of an electronic apparatus using a display device.

### DESCRIPTION OF EMBODIMENTS

Hereinafter, one embodiment and the like according to the present disclosure will be described with reference to the drawings. Here, description will proceed in the following order. In the present specification and the drawings, components having substantially the same functional configuration will be denoted by the same reference numerals, and thus redundant descriptions thereof will be omitted.

Description will be given in the following order.
1. First embodiment
2. Second embodiment
3. Third embodiment
4. Fourth embodiment
5. Application examples

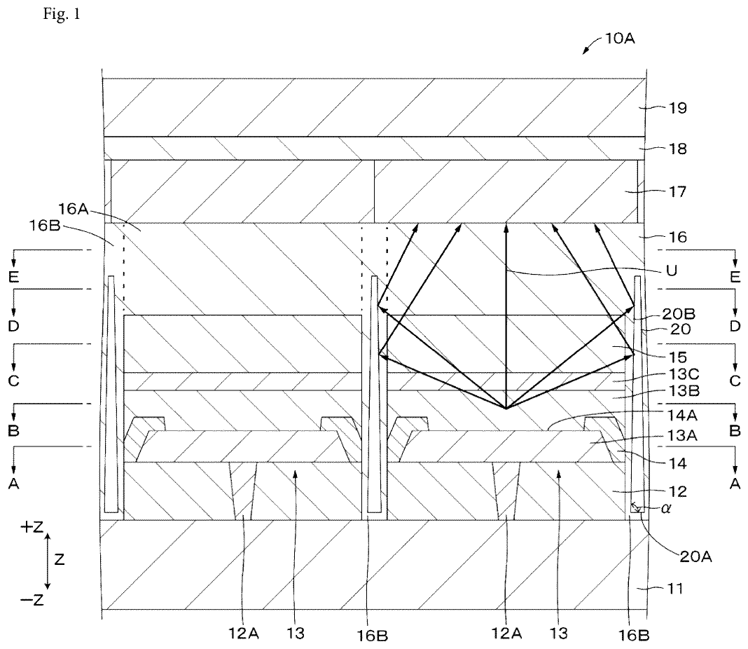

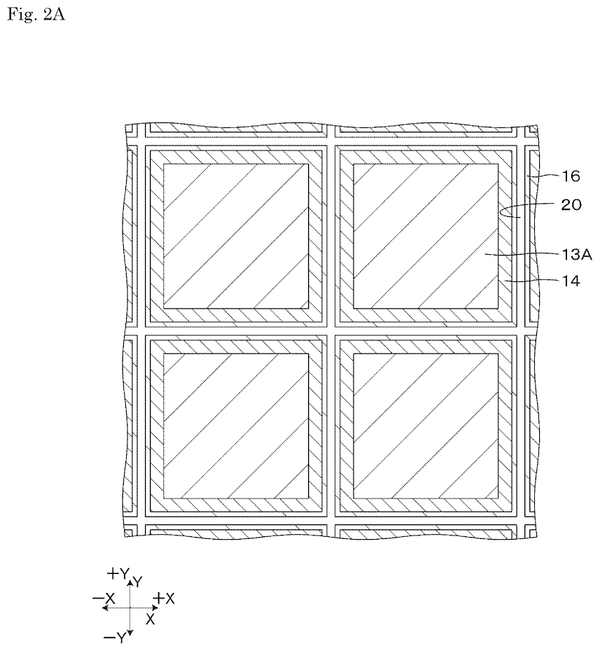

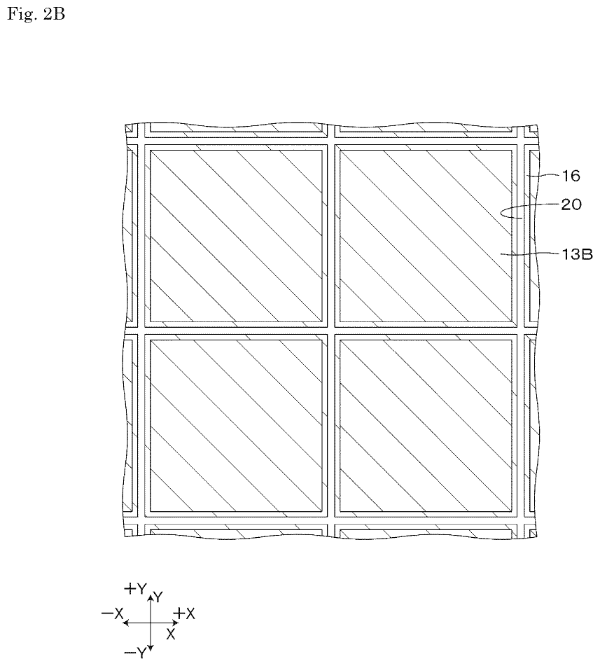

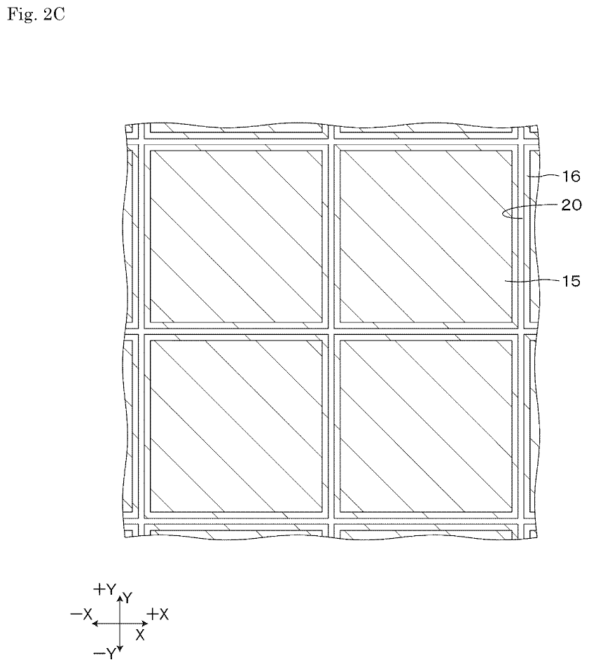

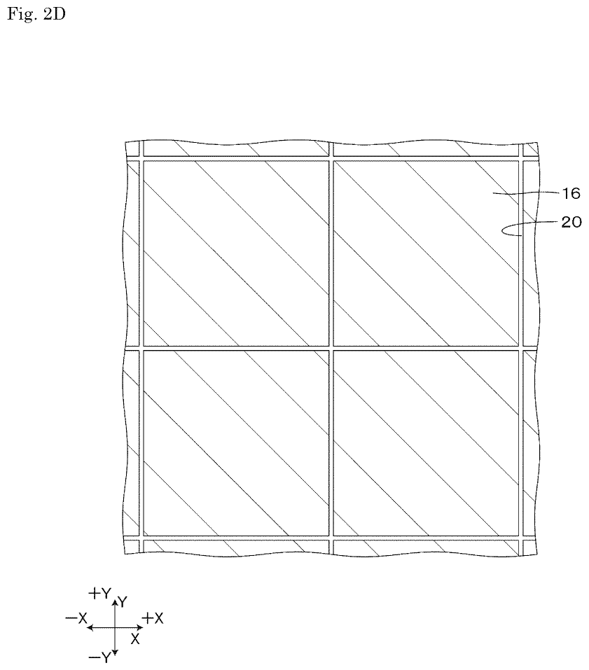

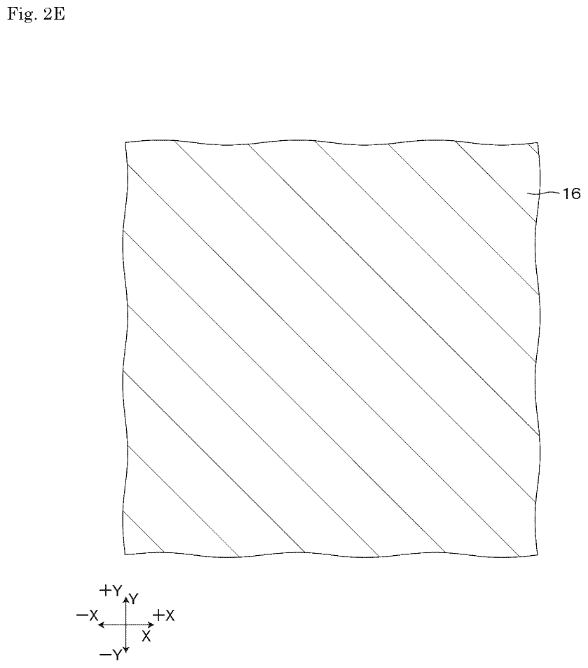

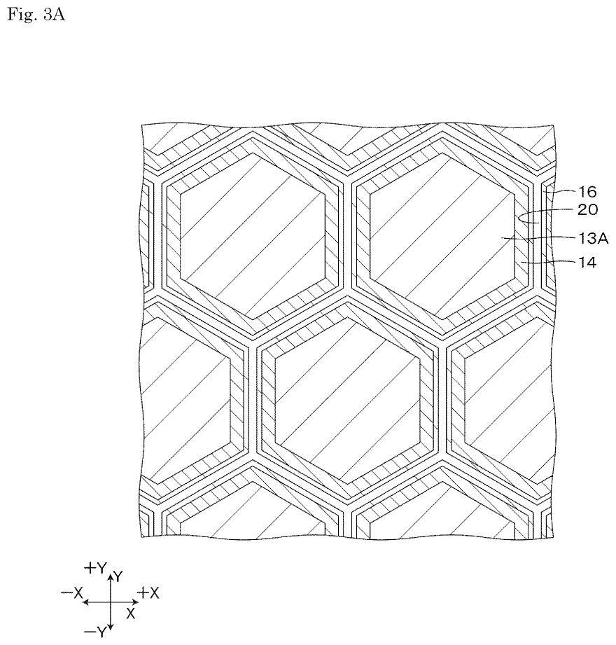

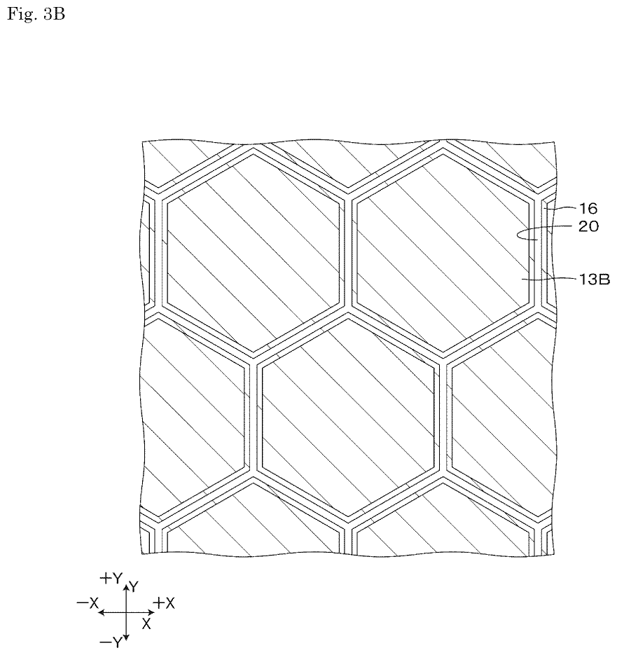

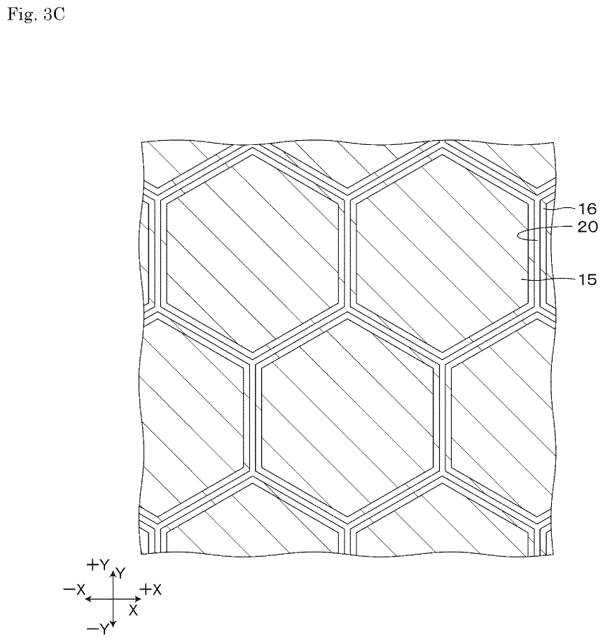

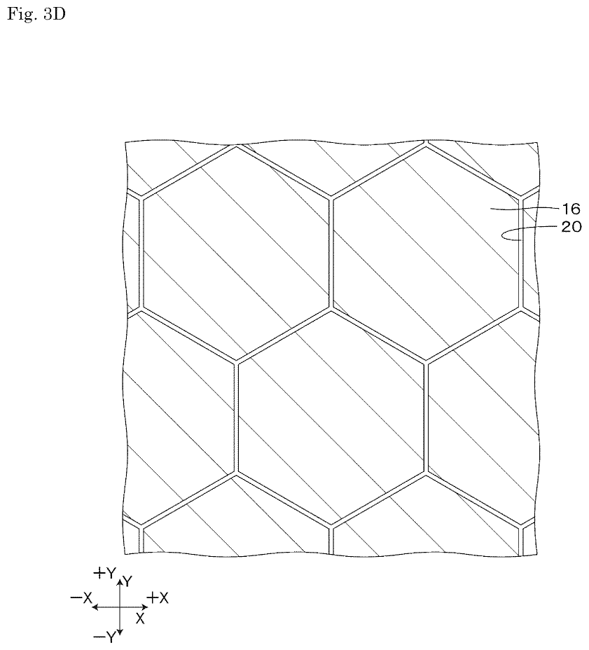

The following description is a preferred specific example of the present disclosure, and the content of the present disclosure is not limited to these embodiments and the like. In addition, in the following description, directions such as forward and backward, left and right, and up and down are shown for convenience of explanation, but the content of the present disclosure is not limited to these directions. In examples of FIG. 1 and FIG. 2A to FIG. 2E, it is assumed that a Z-axis direction is the vertical direction (upward is a +Z direction and downward is a −Z direction), an X-axis direction is the forward-backward direction (forward is a +X direction and backward is a −X direction), a Y-axis direction is the left-right direction (right is a +Y direction and left is a −Y direction), and description will be based thereon. The same applies to FIG. 3A to FIG. 3E and FIG. 4 to FIG. 24. Relative magnitude ratios of the size and thickness of each layer shown in each drawing such as FIG. 1 are denoted for convenience, and does not limit an actual magnitude ratios. Such directions and magnitude ratios apply to each of FIG. 3 to FIG. 24 in the same manner.

### 1. First Embodiment

With respect to a display device according to a first embodiment of the present, an example of a case in which the display device is an organic electro luminescence (EL) display device will be described below.

### 1-1. Configuration of Display Device

FIG. 1 is a cross-sectional view showing a configuration example of an organic EL display device (hereinafter simply referred to as a “display device 10A”) according to first to fourth embodiments of the present disclosure. The display device 10A includes a substrate 11, an insulating layer 12, a plurality of light-emitting elements 13, an insulating layer 14, a protective layer 15, a protective layer 16, a color filter 17, a filled resin layer 18, and a counter substrate 19.

The display device 10A is a top emission type display device. The substrate 11 constitutes the rear surface side of the display device 10A, and the counter substrate 19 constitutes the display surface side of the display device 10A. The counter substrate 19 is the top side and the substrate 11 is the bottom side. In the following description, the surface serving as the display surface side of the display device 10A is referred to as a first surface and the surface serving as the rear surface side of the display device 10A is referred to as a second surface in each layer constituting the display device 10A. In the example of FIG. 1, the surface facing the +Z direction is called the first surface, and the surface facing the −Z direction is called the second surface.

The display device 10A may be a microdisplay. The display device 10A may be used for various electronic apparatuses. Electronic apparatuses using the display device 10A may include, for example, virtual reality (VR), mixed reality (MR), or augmented reality (AR) display devices, electronic view finders (EVFs), small projectors, and the like. This also applies to display devices 10B to 10D which will be described later.

### Substrate 11

The substrate 11 is a so-called backplane and drives the plurality of light-emitting elements 13. On the first surface of the substrate 11, a driving circuit including sampling transistors and driving transistors for controlling driving of the plurality of light-emitting elements 13 and a power supply circuit for supplying power to the plurality of light-emitting elements 13 (both not shown) are provided.

The substrate 11 may be made of, for example, glass or resin with low moisture and oxygen permeability or may be made of a semiconductor that facilitates formation of transistors and the like. Specifically, the substrate 11 may be a glass substrate, a semiconductor substrate, a resin substrate, or the like. Glass substrates contain, for example, high strain point glass, soda glass, borosilicate glass, forsterite, lead glass, or quartz glass. Semiconductor substrates contain, for example, amorphous silicon, polycrystalline silicon, monocrystalline silicon, or the like. Resin substrates contain, for example, at least one selected from a group consisting of polymethyl methacrylate, polyvinyl alcohol, polyvinyl phenol, polyethersulfone, polyimide, polycarbonate, polyethylene terephthalate, polyethylene naphthalate, and the like.

### Insulating Layer 12

The insulating layer 12 is provided on the first surface of the substrate 11 and covers the driving circuit, the power supply circuit, and the like. The insulating layer 12 includes a plurality of contact plugs 12A and a plurality of wires (not shown). Each contact plug 12A connects a lower electrode 13A forming each light-emitting element 13 and the driving circuit. The plurality of wires are arranged adjacently in the in-plane direction (XY plane direction) of the substrate 11, and each wire is electrically connected to the lower electrode 13A and the light-emitting element 13 through the contact plug 12A or the like.

The insulating layer 12 is made of, for example, an organic material or an inorganic material. The organic materials include, for example, at least one of polyimide and acrylic resin. The inorganic materials include, for example, at least one of silicon oxide, silicon nitride, silicon oxynitride, and aluminum oxide.

### Light-Emitting Element 13

The plurality of light-emitting elements 13 are provided on the first surface side of the substrate 11. The plurality of light-emitting elements 13 are two-dimensionally arranged in a prescribed arrangement pattern such as a matrix, for example. The light-emitting elements 13 are configured to emit white light. The light-emitting elements 13 are, for example, white OLEDs or white micro-OLEDs (MOLEDs). In the present embodiment, a method using the light-emitting elements 13 and the color filter 17 is used as a method for colorization in the display device 10A. However, the colorization method is not limited thereto, and an RGB coloring method or the like may be used. Further, instead of the color filter 17, a monochromatic filter may be used. The same colorization method is applied to the display devices 10B to 10D, which will be described later.

Each light-emitting element 13 includes the lower electrode 13A, an organic layer 13B, and an upper electrode 13C. The lower electrode 13A, the organic layer 13B, and the upper electrode 13C are laminated in this order on side of the substrate 11 toward the counter substrate 19.

### Lower Electrode 13A

The lower electrode 13A is provided on the first surface of insulating layer 12. As shown in FIG. 2A, the lower electrode 13A is electrically isolated for each sub-pixel. The lower electrode 13A is an anode. The lower electrode 13A also functions as a reflective layer and is preferably made of a material having as high a reflectance as possible and a high work function in order to increase the luminous efficiency. A sub-pixel indicates a minimum display division unit having one kind of color, obtained by additionally dividing a pixel which is a division unit constituting a screen. For example, a combination of an adjacent red sub-pixel, green sub-pixel and, blue sub-pixel constitutes one pixel.

The lower electrode 13A is composed of at least one of a metal layer and a metal oxide layer. More specifically, the lower electrode 13A is composed of a single layer film of a metal layer or a metal oxide layer, or a laminated film of a metal layer and a metal oxide layer. Although the metal oxide layer may be provided on the side of the organic layer 13B, or the metal layer may be provided on the side of the organic layer 13B when the lower electrode 13A is composed of the laminated film, it is desirable that the metal oxide layer be provided on the side of the organic layer 13B from the viewpoint of placing a layer having a high work function adjacent to the organic layer 13B.

The metal layer contains, for example, at least one metal element selected from a group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the at least one metal element as a constituent element of an alloy. As a specific example of an alloy, an aluminum alloy or a silver alloy may be conceived. As a specific example of an aluminum alloy, for example, AlNd and AlCu may be conceived.

The metal oxide layer contains, for example, at least one of a mixture of indium oxide and tin oxide (ITO), a mixture of indium oxide and zinc oxide (IZO), and titanium oxide (TiO).

### Upper Electrode 13C

The upper electrode 13C is provided facing the lower electrode 13A. The upper electrode 13C is formed directly on the individual organic layers 13B, which will be described later, and adjacent upper electrodes 13C are formed in a state of being spatially isolated for respective sub-pixels and are electrically connected to each other through an electrode connection part (not shown). The electrode connection part may be integrated with or separate from the upper electrode 13C. The upper electrode 13C is a cathode. The upper electrode 13C is a transparent electrode that is transparent to light generated in the organic layer 13B. Here, it is assumed that the transparent electrode includes a semi-transmissive reflective layer. The upper electrode 13C is preferably made of a material having as high a transmittance as possible and a low work function in order to increase the utilization efficiency of light generated by the light-emitting element 13.

The upper electrode 13C is composed of at least one layer of a metal layer and a metal oxide layer. More specifically, the upper electrode 13C is composed of a single layer film of a metal layer or a metal oxide layer, or a laminated film of a metal layer and a metal oxide layer. Although the metal layer may be provided on the side of the organic layer 13B, or the metal oxide layer may be provided on the side of the organic layer 13B when the upper electrode 13C is composed of the laminated film, it is desirable that the metal layer be provided on the side of the organic layer 13B from the viewpoint of placing a layer having a low work function adjacent to the organic layer 13B.

The metal layer contains, for example, at least one metal element selected from a group consisting of magnesium (Mg), aluminum (Al), silver (Ag), calcium (Ca), and sodium (Na). The metal layer may contain the at least one metal element as a constituent element of an alloy. As specific examples of alloys, a MgAg alloy, a MgAl alloy, an AlLi alloy, and the like may be conceived. Metal oxides include, for example, at least one of a mixture of indium oxide and tin oxide (ITO), a mixture of indium oxide and zinc oxide (IZO), and zinc oxide (ZnO).

### Organic Layer 13B

The organic layer 13B is provided between the lower electrode 13A and the upper electrode 13C. The organic layer 13B is patterned according to arrangement of sub-pixels. As shown in FIG. 2B, the organic layer 13B is isolated for each sub-pixel. The organic layer 13B is configured to emit white light.

The organic layer 13B has a structure in which a hole injection layer, a hole transport layer, a light-emitting layer, and an electron transport layer are laminated in this order from the lower electrode 13A toward the upper electrode 13C. The structure of the organic layer 13B is not limited thereto, and layers other than the light-emitting layer are provided as necessary.

The hole injection layer serves to enhance the efficiency of hole injection into the light-emitting layer, and is also a buffer layer for curbing leakage. The hole transport layer serves to enhance the efficiency of hole transport to the light-emitting layer. In the light-emitting layer, recombination of electrons and holes occurs when an electric field is applied to generate light. The light-emitting layer is an organic light-emitting layer containing an organic light-emitting material. The electron transport layer serves to enhance the efficiency of electron transport to the light-emitting layer. An electron injection layer may be provided between the electron transport layer and the upper electrode 13C. This electron injection layer serves to enhance the electron injection efficiency.

### Insulating Layer 14

The insulating layer 14 is provided on the first surface of the insulating layer 12. The insulating layer 14 electrically isolates each lower electrode 13A for each light-emitting element 13 (that is, for each sub-pixel). The insulating layer 14 has a plurality of openings 14A, and the first surface (the surface facing the upper electrode 13C) of the isolated lower electrodes 13A is exposed through the openings 14A. The insulating layer 14 may cover the peripheral portion of the first surface of the isolated lower electrodes 13A to the side surface (end surface) thereof. In the present description, the peripheral portion of the first surface refers to a region having a predetermined width inward from the peripheral edge of the first surface.

### Protective Layer

The protective layer 15 is an upper surface protective layer for protecting the main surface (the surface on the +Z side) on the upper surface side of the light-emitting element 13. The protective layer 15 is provided on the first surface of the upper electrode 13C and covers the light-emitting elements 13 by covering the upper electrode 13C. The protective layer 15 curbs contact between the light-emitting elements 13 and the outside air from the upper surface side of the light-emitting elements 13 and curbs infiltration of moisture into the light-emitting elements 13 from the external environment. Further, when the upper electrode 13C is composed of a metal layer, the protective layer 15 may have a function of curbing oxidation of this metal layer.

The protective layer 15 is made of, for example, an inorganic material. As an inorganic material forming the protective layer 15, one having low hygroscopicity is desirable. Specifically, it is desirable that the inorganic material forming the protective layer 15 include at least one kind selected from a group consisting of silicon oxide (SiO), silicon nitride (SiN), silicon oxynitride (SiNO), titanium oxide (TiO), and aluminum oxide (AlO). The protective layer 15 may have a single-layer structure, but may have a multi-layer structure when the thickness is increased. This is for alleviating the internal stress in the protective layer 15.

### Protective Layer 16

The protective layer 16 has a first protective portion 16A located directly on the protective layer 15 and a second protective portion 16B composed of a portion other than the first protective portion 16A, and the first protective portion 16A and the second protective portion 16B are formed of the same material continuously and integrally. The first protective portion covers the surface of the protective layer 15 serving as an upper surface protective layer, smoothes the surface (surface on the +Z side) along with the second protective portion 16B, and curbs deterioration of the light-emitting element 13. The second protective portion 16B is formed between adjacent first protective portions 16A and is formed to enter between the adjacent protective layer 15 and the adjacent light-emitting element 13. In this example, the second protective portion 16B also enters the insulating layer 12. The second protective portion 16B serves as an element isolation wall that covers the side edge surface 130 of the light-emitting element 13. Unlike the insulating layer 14, the element isolation wall is a wall structure portion that extends in a direction different from the direction of running over the first surface of any one of the layers (the lower electrode 13A, the organic layer 13B, and the upper electrode 13C) of the light-emitting element 13. The second protective portion 16B can curb deterioration of the light-emitting element 13 due to outside air by covering the side edge surface 130 of the light-emitting element 13. The second protective portion 16B extends in the direction (+Z direction) facing the protective layer 15 from the light-emitting element 13 in the thickness direction (Z-axis direction) of the light-emitting element 13 based on the position facing the side edge surfaces 130 of the light-emitting element 13. In the example of FIG. 1, the upper end (extending end) of the second protective portion 16B matches the upper surface side of the first protective portion 16A, and the surface of the first protective portion 16A and the upper end surface of the second protective portion 16B are flush with each other. Although the lower end of the second protective portion 16B is positioned further below the lower electrode 13A of the light-emitting element 13, as shown in the example of FIG. 1, it is desirable from the viewpoint of being able to form a low refractive index portion positioned further below the light-emitting element 13 (a void 20 in the example of FIG. 1).

It is desirable that the material forming the protective layer 16 (the material forming the first protective portion 16A and the second protective portion 16B) have a refractive index lower than that of the protective layer 15 forming the upper surface protective layer in the state of the protective layer 16. In addition, since the refractive index of the protective layer 16 is less than the refractive index of the protective layer 15, it is possible to more effectively prevent light generated by the light-emitting element from leaking to adjacent sub-pixels. Therefore, if the material forming the protective layer 16 satisfies the refractive index as described above, it is possible to more effectively prevent light generated by the light-emitting element from leaking to adjacent sub-pixels.

Further, it is desirable that the material forming the protective layer 16 be a material having a step coverage value of less than 1. Moreover, it is desirable that the material forming the protective layer 16 be a material having lower moisture permeability than the protective layer 15 serving as the upper surface protective layer. By forming the protective layer 16 using such a material, the void 20 can be formed more efficiently.

Materials for forming the protective layer 16 include, for example, SiN, Al₂O₃, TiO₂, and the formed by a method such as a plasma-enhanced chemical vapor deposition (PECVD) method or a sputtering method.

### Low Refractive Index Part

A low refractive index part having a lower refractive index than that of the second protective portion 16B is formed inside the second protective portion 16B forming the element isolation wall. In the example of FIG. 1, the low refractive index part is formed in a shape extending in the thickness direction (Z-axis direction) of the light-emitting element. The low refractive index part is a part having a refractive index lower than that of the second protective portion 16B. Examples of the low refractive index part may include a gas space part filled with a specific gas such as nitrogen, a liquid part filled with a specific liquid, and the like. A void filled with air can be exemplified as a gas space part. The refractive index of the low refractive index part and the refractive index of the second protective portion are the refractive index of the low refractive index part and the refractive index of the second protective portion in the display device. When the refractive index of the void 20 is less than that of the second protective portion 16B, it is easy to cause total reflection of light to occur at the interface between the part made of the material forming the protective layer 16 and the void 20.

### Void

In the example of the display device 10A of FIG. 1, the void 20 is formed as a low refractive index part. An example of a case where the void 20 is formed as a low refractive index part will be continuously described.

The vertical length and position of the void 20 are not limited. The void 20 may be formed at the position of at least one of the lower electrode 13A, the organic layer 13B, the upper electrode 13C, and the protective layer 15, and may have a length corresponding to the position. In the examples of FIG. 1 and FIG. 2A to FIG. 2E, the void 20 is present at the positions of all of the lower electrode 13A, the organic layer 13B, the upper electrode 13C, and the protective layer 15 in the vertical direction (Z-axis direction), and is present up to a height position near the center of the first protective portion 16A in the Z-axis direction. The example of the void 20 is not limited thereto, and for example, it may be formed at the position of the organic layer 13B with a length corresponding to the thickness of the organic layer 13B. However, in order to more accurately curb light leakage to adjacent sub-pixels at the void 20, it is desirable that the upper end of the void 20 be positioned above (+Z direction side) the interface between the light-emitting element 13 and the protective layer 15. It is more desirable that the void 20 be formed from the position near the first surface of the substrate 11 to the position near the second surface of the color filter 17 because it is possible to prevent light generated in the organic layer 13B from leaking to adjacent sub-pixels more reliably. When wires are formed in the insulating layer 12 below the lower electrode 13A, it is desirable that the lower end of the void 20 be positioned below the lower electrode 13A like the lower end of the second protective portion 16B, and it is more desirable that it be positioned at a position between adjacent wires in the insulating layer 12 or a position lower than a position between adjacent wires. In this case, since the void 20 is disposed between wires adjacent to each other in the XY plane direction, the electrostatic capacitance (parasitic capacitance) of a capacitor formed by the adjacent wires can be reduced as compared to a case where the void 20 is not present.

In the example of FIG. 1, the cross-sectional shape of the void 20 has a bottom surface portion 20A and a sidewall portion 20B. To enhance light extraction efficiency, it is desirable that a taper angle (angle α in FIG. 1) formed by the bottom surface portion 20A and the sidewall portion 20B be 90° or less in the void 20. In addition, to facilitate total reflection of light and curb light leakage, it is more desirable to form a forward tapered shape in which the taper angle α is 30° or less. However, this does not prohibit the void 20 from having a reverse tapered shape, and the void 20 may have a reverse tapered shape.

In the example of FIG. 1, the cross-sectional shape of the void 20 is a trapezoidal cross section, but it is not limited thereto and may be a triangle, a polygon with a quadrangle or more, or may have a curved surface.

If emphasis is placed only on the effect of curbing the reflection of light emitted from the organic layer 13B of the light-emitting element 13 and traveling obliquely upward with respect to the vertical direction, the void 20 may be formed only between the adjacent protective layers 15. In that case, the second protective portion 16B in the protective layer 16 may be formed only between the adjacent protective layers 15, or may be formed over the between the adjacent protective layers 15 and the portion between the adjacent light-emitting elements 13. When the second protective portion 16B is formed only between the adjacent protective layers 15, the organic layer 13B and the upper electrode 13C are not isolated for each sub-pixel and are shared between sub-pixels.

### Color Filter

The color filter 17 is provided on the protective layer 16. The color filter 17 is, for example, an on-chip color filter (OCCF). The color filters 17 include, for example, a red filter, a green filter, and a blue filter. The red filter, the green filter, and the blue filter are provided facing a light-emitting element 13 for a red sub-pixel, a light-emitting element 13 for a green sub-pixel, and a light-emitting element 13 for a blue sub-pixel, respectively. Accordingly, white light emitted from the light-emitting elements 13 in the red sub-pixel, the green sub-pixel, and the blue sub-pixel is transmitted through the red filter, the green filter, and the blue filter, and thus red light, green light, and blue light are emitted from the display surface. Further, a light shielding layer (not shown) may be provided in a region between color filters of the respective colors, that is, between sub-pixels. The color filter 17 is not limited to the on-chip color filter and may be provided on one main surface of the counter substrate 19.

### Filled Resin Layer

The filled resin layer 18 is provided between the color filter 17 and the counter substrate 19. The filled resin layer 18 functions as an adhesive layer that bonds the color filter 17 and the counter substrate 19 to each other. The filled resin layer 18 contains, for example, at least one of a thermosetting resin and an ultraviolet curable resin.

### Counter Substrate

The counter substrate 19 is provided facing the substrate 11. More specifically, the counter substrate 19 is provided such that the second surface of the counter substrate 19 and the first surface of the substrate 11 face each other. The counter substrate 19 and the filled resin layer 18 seal the light-emitting elements 13, the color filter 17, and the like. The counter substrate 19 is made of a material such as glass that is transparent to each color of light emitted from the color filter 17.

### 1-2 Method of Manufacturing Display Device

Hereinafter, an example of a method of manufacturing the display device 10A according to the first embodiment of the present disclosure will be described.

First, a driving circuit, a power supply circuit, and the like are formed on the first surface of the substrate 11 using, for example, thin film formation technology, photolithography technology, and etching technology. Next, the insulating layer 12 is formed on the first surface of the substrate 11 to cover the driving circuit and the power supply circuit by, for example, a CVD method, and then the plurality of contact plugs 12A are formed in the insulating layer 12.

Next, a laminated film of a metal layer and a metal oxide layer is formed on the first surface of the substrate 11 by, for example, a sputtering method, and then the laminated film is patterned by, for example, photolithography technology and etching technology to form the lower electrode 13A isolated for each light-emitting element 13 (that is, for each sub-pixel).

Next, the insulating layer 14 is formed on the first surface of the insulating layer 12 to cover the plurality of lower electrodes 13A by, for example, a CVD method, and then the insulating layer 14 is patterned using photolithography technology and etching technology. Accordingly, a plurality of openings 14A are formed in the insulating layer 14. The insulating layer 14 may be omitted if the lower electrode 13A is unlikely to be damaged by processing for forming a groove (grooving), which will be described later.

Next, a hole injection layer, a hole transport layer, a light-emitting layer, and an electron transport layer are laminated in this order on the first surface of the first surface the lower electrode 13A by, for example, an evaporation method, thereby forming the organic layer. 13B. Next, the upper electrode 13C is formed on the first surface of the organic layer 13B by, for example, an evaporation method or a sputtering method. Accordingly, a plurality of light-emitting elements 13 are formed on the first surface of the insulating layer 12.

Next, the protective layer 15 is formed on the first surface of the upper electrode 13C by, for example, a CVD method or an evaporation method. Then, grooving is performed for the light-emitting elements and the protective layer according to the layout of sub-pixels by, for example, photolithography technology and etching technology. In the display device of FIG. 1, a groove is formed to the inside of the insulating layer 12. Further, the protective layer 16 is formed on the surface of the protective layer 15 and inside of the groove by a method such as PECVD or sputtering. At this time, by adjusting the aspect ratio of the groove, the taper angle between the bottom surface and the side surface of the groove, the thickness and coverage of the second protective portion 16B serving as an element isolation wall, and the like, the void 20 is formed in the second protective portion 16B.

After the protective layer 16 is formed, the color filter 17 is formed on the first surface of the protective layer 15 by photolithography, for example. Next, after the color filter 17 is covered with the filled resin layer 18 using, for example, One Drop Fill (ODF) method, the counter substrate 19 is placed on the filled resin layer 18. Next, the filled resin layer 18 is heated or irradiated with ultraviolet rays, for example, to be hardened, thereby attaching the substrate 11 and the counter substrate 19 to each other through the filled resin layer 18. Accordingly, the display device 10A is sealed. As described above, the display device 10A shown in FIG. 1 is obtained.

### 1-3 Operations and Effects

In the display device according to the first embodiment, as shown in FIG. 1, the second protective portion 16B serving as an element isolation wall is formed between adjacent sub-pixels to face the side edge surface 130 of the light-emitting element 13, and the low refractive index part is formed in the second protective portion 16B. Accordingly, light U generated by the light-emitting element 13 is reflected by the low refractive index part, and thus leakage of light generated in the organic layer 13B to adjacent sub-pixels can be curbed.

In addition, in the display device according to the first embodiment, when the low refractive index part is the void 20, and the void 20 is formed to the depth of a position between adjacent wires of the insulating layer 12 below the lower electrode 13A, capacitance between wires (parasitic capacitance) can be reduced.

### 1-4 Modified Example

Although the shape of the sub-pixel is rectangular in the above description of the display device 10A, it is not limited thereto and may be a hexagonal shape as shown in FIG. 3A to FIG. 3E. Further, the arrangement of sub-pixels is not limited to a matrix pattern and may be a honeycomb pattern as shown in FIG. 3A to FIG. 3E. Even in such a case, it is possible to prevent light from leaking to adjacent sub-pixels in the same manner as described above.

### 2 Second Embodiment

A display device according to a second embodiment of the present disclosure will be described below using an example in which the display device is an organic EL display device as in the first embodiment.

### 2-1. Configuration of Display Device

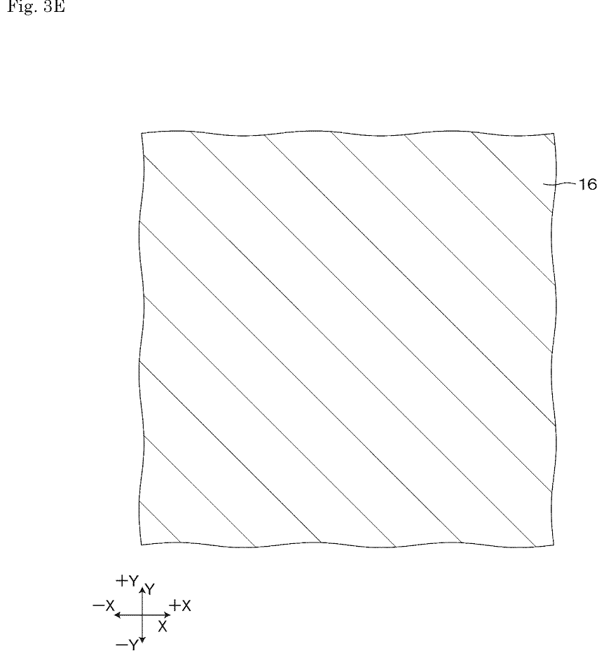

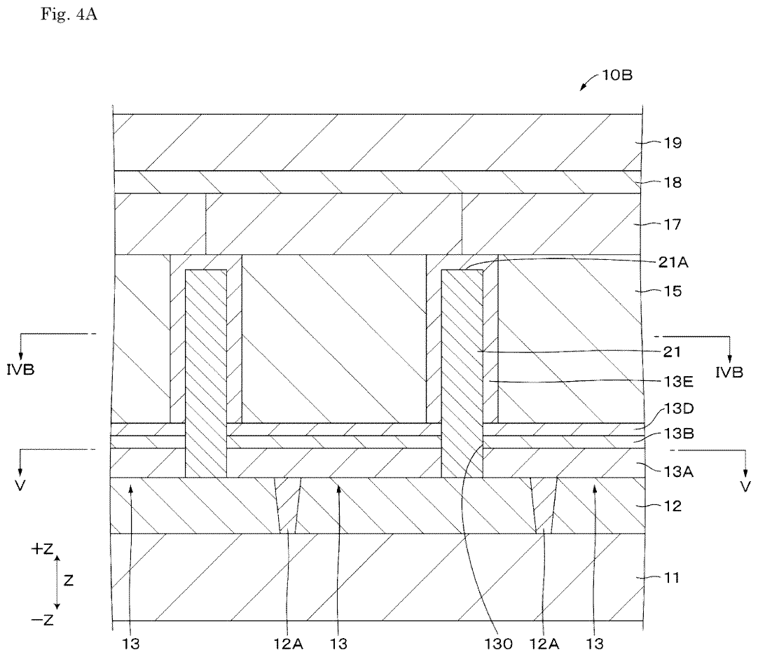

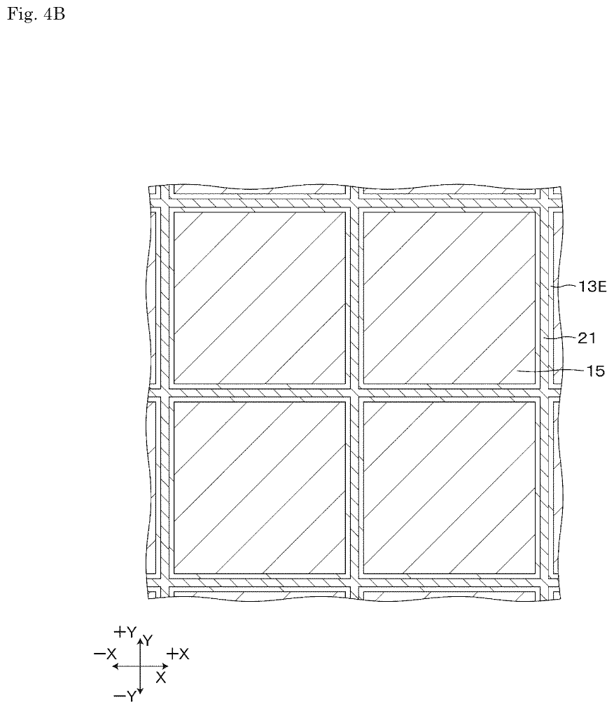

FIG. 4A is a cross-sectional view showing a configuration example of an organic EL display device (display device 10B) according to an example of the second embodiment. FIG. 4B is a diagram illustrating a state of a cross section taken along line IVB-IVB in FIG. 4A. The display device 10B is a top emission type display device. The display device 10B includes a substrate 11, an insulating layer 12, a plurality of light-emitting elements 13, a protective layer 15 serving as an upper surface protective layer, an isolation film 21 serving as an element isolation wall, a color filter 17, and a filled resin layer 18, and a counter substrate 19.

The substrate 11, the insulating layer 12, the protective layer 15, the color filter 17, the filled resin layer 18, and the counter substrate 19 are the same as those in the first embodiment. In the display device 10B of the second embodiment, the structure of the insulating layer 14 in the first embodiment may not be provided.

### Light-Emitting Element 13

As in the first embodiment, the plurality of light-emitting elements 13 are provided on the first surface of the substrate 11 and include a lower electrode 13A, an organic layer 13B, and a first upper electrode 13D as an upper electrode laminated on the organic layer 13B. The lower electrode 13A and the organic layer 13B are isolated for each sub-pixel as in the first embodiment.

### Upper Electrode (First Upper Electrode)

The upper electrode laminated on the organic layer 13B is the first upper electrode 13D and is isolated for each sub-pixel. The first upper electrode 13D faces the lower electrode 13A, and the first upper electrode 13D faces the protective layer 15.

### Second Upper Electrode

A second upper electrode 13E electrically connects adjacent first upper electrodes 13D to each other. The second upper electrode 13E extends along the surface of the isolation film 21 to an extending end 21A of the isolation film 21 with the position where the first upper electrode 13D and the isolation film 21 face each other as a base end. In the example of FIG. 4A, the position of the upper end of the second upper electrode 13E and the position of the surface of the protective layer 15 are aligned in a state in which the second upper electrode 13E is formed on the surface of the isolation film 21.

In addition, in the example of FIG. 4A and FIG. 4B, the second upper electrode 13E is formed to cover the entire portion of the isolation film 21 which extends upward beyond the first upper electrode 13D. In this case, if the second upper electrode 13E is made of a reflective material as will be described later, obliquely traveling light emitted from the light-emitting elements 13 can be effectively reflected by the second upper electrode 13E, and thus light utilization efficiency can be improved. In the example of FIG. 4B, the second upper electrodes 13E are formed in a grid pattern according to the layout of sub-pixels, and the individual first upper electrodes 13D are formed in a rectangular shape and arranged in a matrix.

The first upper electrode 13D and the second upper electrode 13E are cathodes. The first upper electrode 13D is a transparent electrode that is transparent to light generated in the organic layer 13B. Here, it is assumed that the transparent electrode includes a semi-transmissive reflective layer. It is desirable to form the first upper electrode 13D using a material having as high transmittance as possible and a low work function in order to increase the luminous efficiency.

It is desirable that the reflectance of the second upper electrode 13E be higher than the reflectance of the first upper electrode 13D. The reflectance of the second upper electrode 13E and the reflectance of the first upper electrode 13D are the reflectance of the second upper electrode 13E and the reflectance of the first upper electrode 13D in the state of the display device 10B. From this point of view, not only the same material as the first upper electrode 13D but also a reflective material can be used as the material of the second upper electrode 13E. As a reflective material, silver (Ag), aluminum (Al), tungsten (W), and the like can be conceived.

### Isolation Film

In the display device 10B, the isolation film 21 is formed as an element isolation wall to cover the side edge surface 130 of the light-emitting element 13. The isolation film 21 is disposed adjacent light-emitting elements 13 and isolates the lower electrode 13A, the organic layer 13B, and the first upper electrode 13D forming the light-emitting element 13 for each sub-pixel.

The upper end portion of the isolation film 21 extends from the light-emitting element 13 toward the protective layer 15 in the thickness direction (Z-axis direction) of the light-emitting element 13. Since the isolation film 21 extends in the direction (Z-axis direction) toward the protective layer 15 from the light-emitting element 13 instead of in the plane direction (XY plane direction) of the light-emitting element 13, it is difficult for the isolation film 21 to cover the light-emitting region of the light-emitting element, and thus a wider light-emitting region can be secured.

The isolation film 21 is made of an insulator. As the isolation film 21, an inorganic insulating film or an organic insulating film can be conceived. As an inorganic insulating film, SiO₂, SiN, SiON, or the like can be conceived. As an organic insulating film, polyimide or the like can be conceived.

It is desirable that the length of the isolation film 21 in the vertical direction (Z-axis direction) be greater than the sum of the thickness of the lower electrode 13A, the thickness of the organic layer 13B, and the thickness of the first upper electrode 13D in order to form a portion of the isolation film 21 which extends upward beyond the first upper electrode 13D.

In the example of FIG. 4A, the lower end of the isolation film 21 is positioned near the insulating layer 12 below the lower end of the lower electrode 13A, and the isolation film 21 isolates the lower electrode 13A for each sub-pixel. The isolation film 21 may be positioned at the lower end of the lower electrode 13A. The isolation film 21 may isolate the lower electrode 13A for each sub-pixel.

In the example of FIG. 4A, the upper end of the isolation film 21 is positioned slightly below the position of the surface of the protective layer 15, and the position of the extending end of the second upper electrode 13E and the position of the surface of the protective layer 15 are aligned in a state in which the second upper electrode 13E is positioned on the surface of the isolation film 21.

### Refractive Index

It is desirable that the refractive index of the isolation film 21 be less than that of the second upper electrode 13E. In this case, obliquely traveling light among light generated by the light-emitting elements 13 can be totally reflected at the interface between the second upper electrode 13E and the isolation film 21, and thus light utilization efficiency can be improved. The refractive index of the isolation film 21 and the refractive index of the second upper electrode 13E are the refractive index of the isolation film 21 and the refractive index of the second upper electrode 13E in the state of the display device 10B.

### 2-2 Method of Manufacturing Display Device

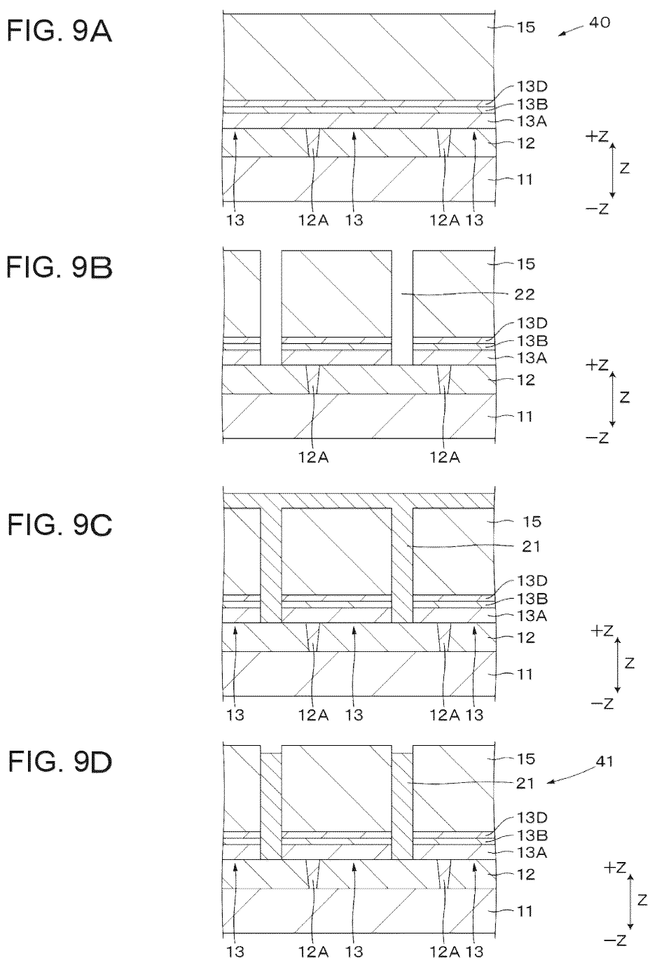

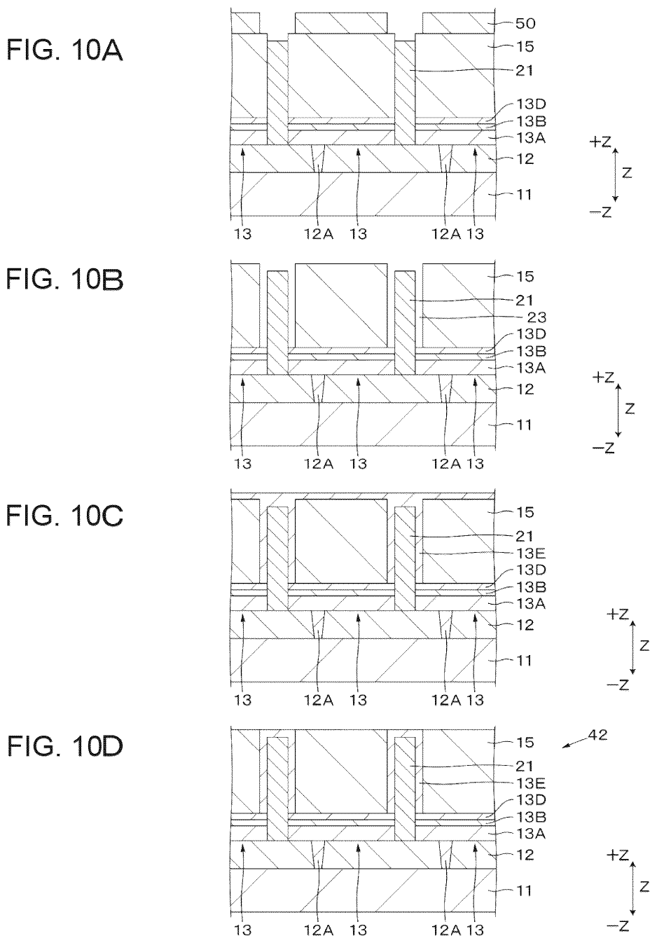

A method of manufacturing the display device according to the second embodiment can be implemented, for example, as described below with reference to FIG. 9A to FIG. 9D and FIG. 10A to FIG. 10D. FIG. 9A to FIG. 9D and FIG. 10A to FIG. 10D are diagrams for describing the method of manufacturing the display device 10B according to the second embodiment.

A process of forming a first laminate in which the lower electrode 13A, the organic layer 13B, the first upper electrode 13D, and the protective layer 15 are laminated in this order on the substrate 11 on which the insulating layer 12 is formed is carried out as follows.

A driving circuit, a power supply circuit, and the like are formed on the first surface of the substrate 11 using, for example, thin film formation technology, photolithography technology, and etching technology. Next, the insulating layer 12 is formed on the first surface of the substrate 11 to cover the driving circuit and the power supply circuit by, for example, a CVD method, and then the plurality of contact plugs 12A are formed in the insulating layer 12.

A laminated film (lower electrode) of a metal layer and a metal oxide layer is formed on the first surface of the substrate 11 by, for example, a sputtering method. Next, a hole injection layer, a hole transport layer, a light-emitting layer, and an electron transport layer are laminated in this order on the first surface of the lower electrode 13A, for example, by an evaporation method to form the organic layer 13B. Further, the first upper electrode 13D is formed on the first surface of the organic layer 13B by an evaporation method or a sputtering method, for example. Accordingly, a plurality of light-emitting elements 13 are formed on the substrate 11 (on the first surface of the insulating layer 12). Thereafter, the protective layer 15 is formed on the first surface of the first upper electrode 13D by, for example, a CVD method of an evaporation method. Accordingly, a first laminate 40 is formed as shown in FIG. 9A.

Next, as shown in FIG. 9B, a process of forming a first groove from the protective layer 15 to a predetermined depth (first grooving process) at a predetermined position in the first laminate 40 according to the layout of sub-pixels is performed. The first grooving process is a process of performing grooving on the light-emitting element 13 and the protective layer 15 according to the layout of the sub-pixels by, for example, photolithography technology and etching technology. In the display device of FIG. 4A, a first groove 22 is formed by collectively performing grooving on the protective layer 15, the first upper electrode 13D, the organic layer 13B, the lower electrode 13A, and the insulating layer 12.

Then, a process of forming the isolation film 21 in the first groove 22 is performed by a method such as a chemical vapor deposition (CVD) method, a coating method, or the like. At this time, the material forming the isolation film 21 is also laminated on the outer side of the first groove 22, such as on the surface of the protective layer 15, and thus the outer laminated portion of the first groove 22 is formed as shown in FIG. 9C, but this outer laminated portion of the first groove 22 is removed by a chemical mechanical polishing (CMP) method, an etch-back method, or the like. Accordingly, a second laminate 41 is formed as shown in FIG. 9D. For example, inorganic insulating films such as SiO₂, SiN, and SiON can be formed by the CVD method. For example, an organic insulating film such as polyimide can be formed by the coating method.

A process of forming a second groove 23 from the protective layer 15 to the position of the first upper electrode 13D in a predetermined region around the isolation film 21 in the second laminate 41 (second grooving process) is performed. As shown in FIG. 10A and FIG. 10B, the second grooving process is a process of performing grooving, for example, photolithography technology and etching technology in the same manner as the above-described first grooving process. The depth of the second groove 23 reaches the first upper electrode 13D, and the first upper electrode 13D is exposed to the bottom surface of the second groove 23. Reference numeral 50 in FIG. 10A denotes a resist for forming the second grooves 23.

Then, a process of forming the second upper electrode 13E in the second groove 23 is performed. At this time, the material forming the second upper electrode is also laminated outside the second groove, such as on the surface of the protective film, and thus the outer laminated portion of the second groove 23 is formed as shown in FIG. 10C, but this outer laminated portion of the second groove is removed by a CMP method, an etch-back method, or the like as in the case of the outer laminated portion of the first groove. Accordingly, a third laminate 42 is formed as shown in FIG. 10D. The outer laminated portion of the second groove 23 is left without being removed in the case of modified example 3 of the second embodiment, which will be described later.

After the second upper electrode 13E is formed, the color filter 17 is formed on the first surface of the third laminate 42 by photolithography, for example. Next, after the color filter 17 is covered with the filled resin layer 18 using, for example, One Drop Fill (ODF) method, the counter substrate 19 is placed on the filled resin layer 18. Next, the filled resin layer 18 is heated or irradiated with ultraviolet rays, for example, to be hardened, thereby attaching the substrate 11 and the counter substrate 19 to each other through the filled resin layer 18. Accordingly, the display device 10B is sealed. As described above, the display device 10B is obtained.

### 2-3 Operations and Effects

According to the display device according to the second embodiment, the lower electrode 13A, the organic layer 13B, and the first upper electrode 13D forming the light-emitting element 13 are isolated for each sub-pixel by the isolation film 21. Accordingly, it is possible to curb unintended light emission due to current leakage around sub-pixels. In addition, since the organic layer 13B is surrounded by the isolation film 21 and isolated for each sub-pixel, as shown in FIG. 4B, it is possible to curb lateral light leakage to adjacent sub-pixels. Furthermore, since the isolation film 21 extends in the vertical direction, it becomes easier to secure a wider light-emitting region of the light-emitting element as compared to a case in which an insulating film is formed to run over the periphery of the first electrode patterned for each sub-pixel and isolated for each sub-pixel.

According to the display device according to the second embodiment, the reflectance of the second upper electrode 13E is higher than that of the first upper electrode 13D, and thus light generated by the light-emitting element 13 is reflected by the second upper electrode 13E, and light generated by the light-emitting element 13 can be curbed from leaking to adjacent sub-pixels.

According to the display device according to the second embodiment, since the isolation film 21 has a lower refractive index than the second upper electrode 13E, light generated by the light-emitting element 13 totally reflected at the interface of the second upper electrode 13E and the isolation film 21, and thus it is possible to curb leakage of light generated by the light-emitting element 13 to adjacent sub-pixels (curb light leakage between adjacent pixels).

In addition, according to the display device according to the second embodiment, by curbing leakage of light generated by the light-emitting element 13 to adjacent sub-pixels in this manner, color mixture can be curbed and thus deterioration of a viewing angle can be curbed.

### 2-4 Modified Examples

### Modified Example 1

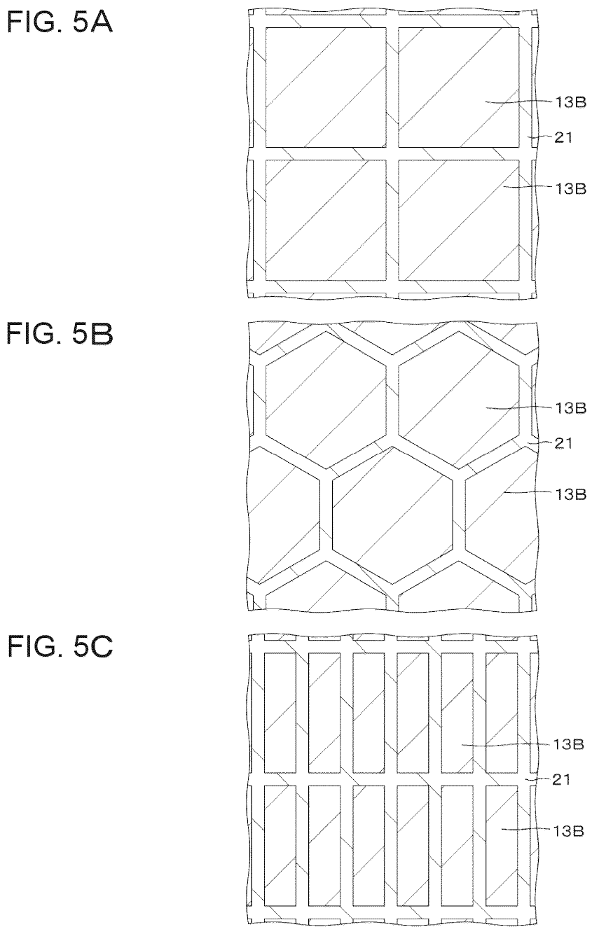

In the above description of the display device 10B, the shape of the sub-pixel is a rectangular shape as shown in FIG. 4B and FIG. 5A, and a plurality of sub-pixels are separately arranged in a matrix. In the display device 10B according to the second embodiment, the shape of the sub-pixel is not limited thereto and may be a hexagonal shape or a striped shape, as shown in FIG. 5B and FIG. 5C. Further, the arrangement of the sub-pixels is not limited to a matrix pattern, and may be a honeycomb pattern as shown in FIG. 5B. Even in such a case, unintended light emission due to current leakage is curbed in the same manner as described in the above operations and effects. In addition, it is possible to curb leakage of light to adjacent sub-pixels.

### Modified Example 2

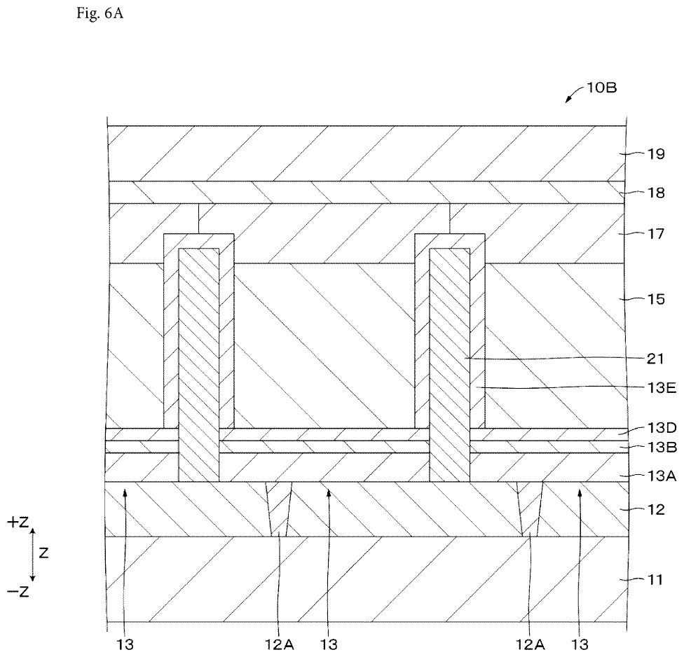

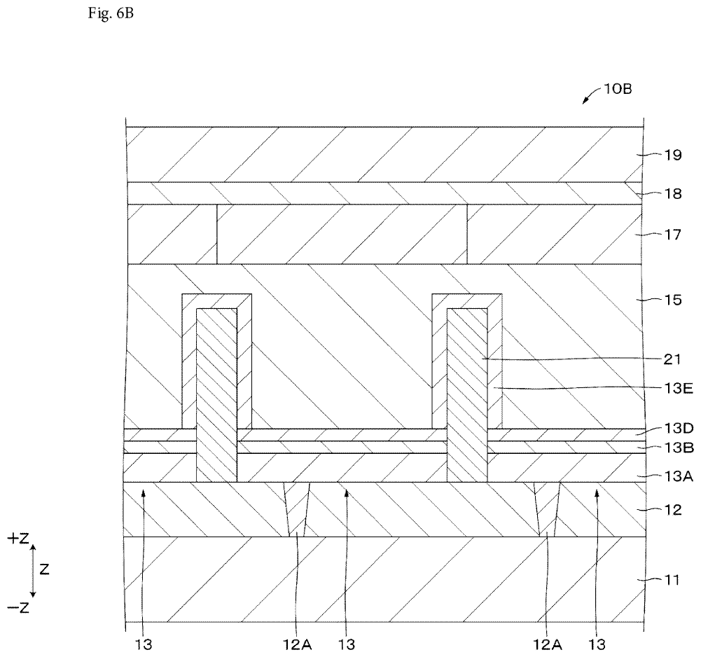

Regarding the display device 10B according to the second embodiment, an example of a case in which the position of the extending end of the second upper electrode 13E and the surface of the protective layer 15 are aligned in a state in which the second upper electrode 13E is formed on the surface of the isolation film 21 has been described. The display device 10B according to the second embodiment is not limited to this example, and the extending end of the second upper electrode 13E may be positioned further upward (+Z direction) beyond the position of the surface of the protective layer 15 and enter the color filter 17, as shown in FIG. 6A, or may not reach the position of the surface of the protective layer 15, as shown in FIG. 6B.

### Modified Example 3

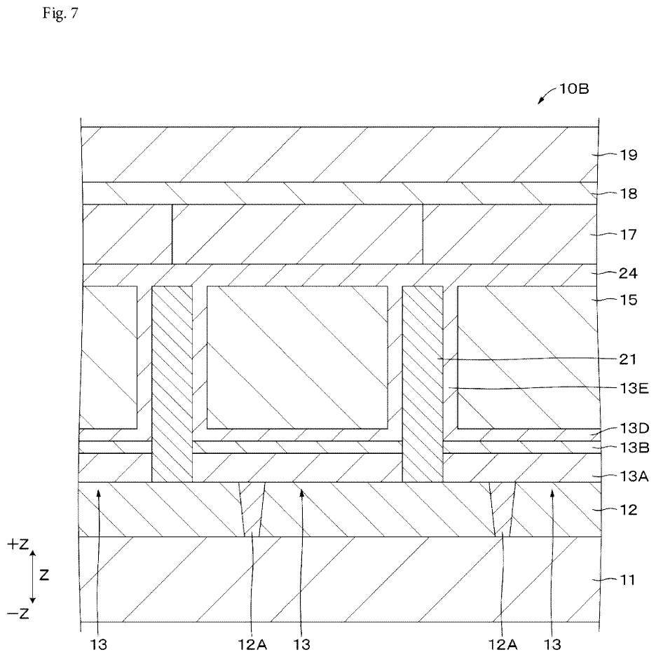

Regarding the display device 10B according to the second embodiment, the second upper electrode 13E is formed along the surface of the isolation film 21 to cover the surface of the isolation film 21 in the above description. The display device 10B according to the second embodiment is not limited to this example. As shown in the example of FIG. 7, the second upper electrode 13E is not only formed along the surface of the isolation film 21 to the extending end of the isolation film 21, but also may extend along the surface of the protective layer 15 from the extending end of the isolation film 21. A portion of the second upper electrode 13E which extends along the surface of the protective layer 15 is called an extended electrode portion 24. It is desirable that the extended electrode portion 24 cover the entire surface of the protective layer 15. In this case, it is desirable that the second upper electrode 13E be a transparent or translucent electrode in order to allow light generated from the light-emitting element 13 to pass through the extended electrode portion 24 and be efficiently extracted to the outside.

When the second upper electrode 13E is formed as a translucent electrode, the second upper electrode 13E has an extended electrode portion, and it is possible to improve the light extraction effect according to light resonance effect by adjusting the distance between the light-emitting surface of the organic layer 13B and the extended electrode portion 24, which makes it possible to obtain the display device 10B with high brightness.

### Modification Example 4

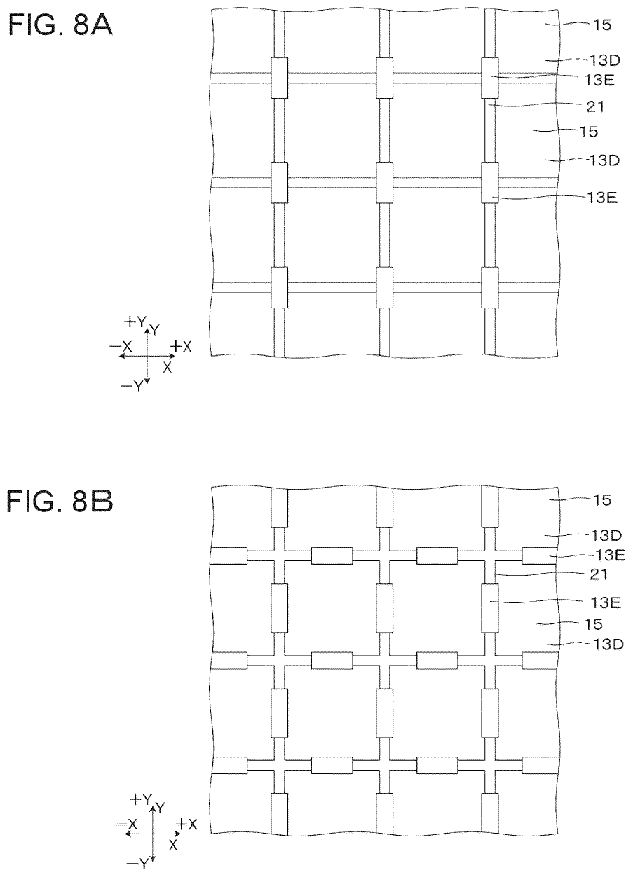

Although the second upper electrode 13E is formed to cover the entire surface of the portion of the isolation film 21 extending upward from the first upper electrode 13D, the display device 10B according to the second embodiment is not limited to this example, and the second upper electrode 13E may be formed to cover a part of the portion of the isolation film 21 extending upward from the first upper electrode, as shown in FIG. 8A and FIG. 8B.

For example, as shown in the example of FIG. 8A, the second upper electrode 13E may be formed to cover a part of the portion of the isolation film 21 extending upward from the first upper electrode 13D, which corresponds to the peak portion of an adjacent sub-pixel. In addition, as shown in the example of FIG. 8B, the second upper electrode 13E may be formed to cover a part of the portion of the isolation film 21 extending upward from the first upper electrode 13D, which corresponds to the side portion of an adjacent sub-pixel.

### 3 Third Embodiment

In the display device 10B according to the second embodiment, a sidewall protective film may be interposed between the side edge surface of the organic layer 13B and the isolation film 21 (third embodiment).

With respect to a display device according to the third embodiment of the present disclosure, an example of a case in which the display device is an organic EL display device as in the second embodiment will be described below with reference to FIG. 11 and the like. FIG. 11 is a cross-sectional view showing a configuration example of an organic EL display device (display device 10C) according to an example of the third embodiment.

### 3-1. Configuration of display device

The display device 10C has a sidewall protective film in addition to the components of the display device 10B according to the second embodiment. As shown in the example of FIG. 11, the display device 10C includes the substrate 11, the insulating layer 12, the plurality of light-emitting elements 13, the protective layer 15, a sidewall protective films 25, the isolation film 21 serving as an element isolation wall, the color filter 17, the filled resin layer 18, and the counter substrate 19.

### Sidewall Protective Film

The sidewall protective film 25 is interposed between the side edge surface of the organic layer 13B and the isolation film 21. As shown in FIG. 11, it is desirable that the sidewall protective film 25 cover the entire side edge surface the organic layer 13B while being in contact with the side edges of the organic layer 13B.

The sidewall protective film 25 is an insulating film and is a processing by-product film containing a by-product (deposit) generated in etching processing. The sidewall protective film 25 assists in forming the isolation film 21 while restricting exposure of the organic layer 13B to the external environment. Etching processing mentioned here indicates processing by an etching method in first grooving processing described in a method of manufacturing the display device 10C according to the third embodiment, which will be described later. As etching processing, both a dry etching method and a wet etching method can be performed, but it is desirable that etching processing be a dry etching method in order to realize deposition more reliably.

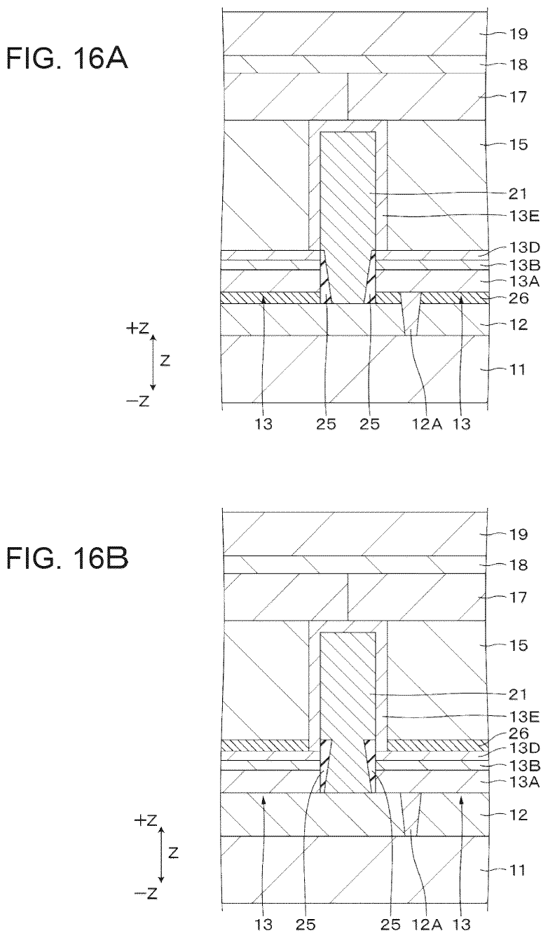

Although the sidewall protective film 25 shown in FIG. 11 is formed to have a uniform thickness, this is not limited to a case where the sidewall protective film 25 has a uniform thickness. For example, as shown in FIG. 16A, the sidewall protective film 25 may be formed such that the thickness gradually decreases with increasing distance from the vicinity of an assistance layer 26, which will be described later.

### Assistance Layer

To facilitate more reliable formation of deposit during etching processing, it is desirable that the assistance layer 26 be interposed between the lower electrode 13A and the substrate 11 or between the first upper electrode 13D and the protective layer 15. In the example of FIG. 11, the assistance layer 26 is formed between the lower electrode 13A and the substrate 11 under the lower electrode 13A. In the example of FIG. 11, the contact plugs 12A are also formed in the assistance layer 26 to ensure electrical connection with the driving circuit on the side of the substrate 11.

The assistance layer 26 is a deposit-forming film made of a material that easily forms deposit during etching processing. As a material for the assistance layer 26, which easily forms a by-product (deposit) during etching processing, for example, a hard-to-etch material having a lower metal halide compound volatility and a stronger metal-oxygen bond is suitably used. Specifically, as the material of the assistance layer 26, it is desirable to use a transition metal oxide such as Al₂O₃. However, this does not limit the material of the assistance layer 26 to a transition metal oxide. The material of the assistance layer 26 may be any material that can form an insulating film on the side edge surface of the organic layer 13B.

When the assistance layer 26 is provided, the sidewall protective film 25 is formed to extend from the assistance layer 26 along the side edge surface 130 of the light-emitting element 13 with the assistance layer 26 as a base end. In this case, the sidewall protective film 25 contains at least one element forming the assistance layer 26. The film composition of the sidewall protective film 25 is different from the film composition of the isolation film 21.

### 3-2 Method of Manufacturing Display Device

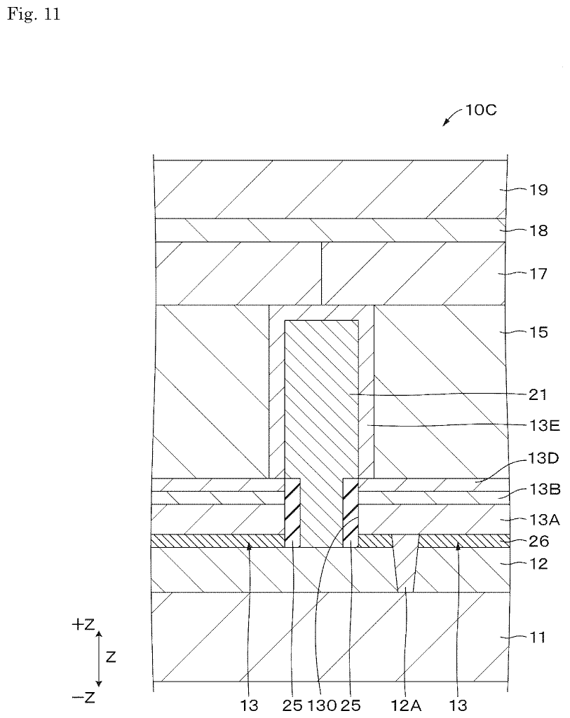

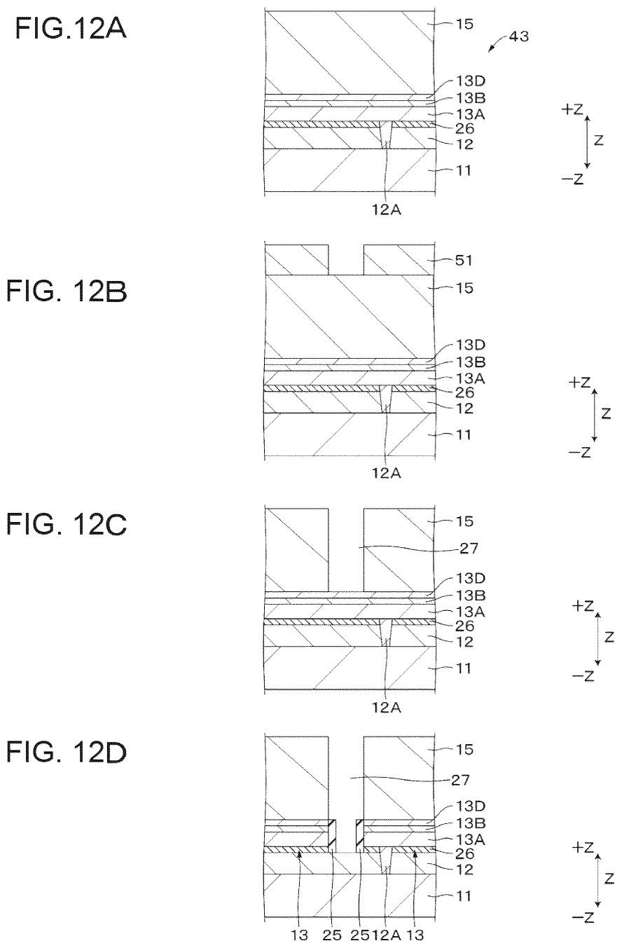

A method of manufacturing the display device according to the third embodiment can be implemented, for example, as described below with reference to FIG. 12A to FIG. 12D.

As shown in FIG. 12A, the assistance layer 26, the lower electrode 13A, the organic layer 13B, the first upper electrode 13D, and the protective layer 15 are laminated in this order on the substrate 11 on which the insulating layer 12 is formed to form a first laminate 43. Further, a resist 51 is provided on the first laminate 43 as shown in FIG. 12B, and a first groove 27 is formed in the protective layer 15 at a predetermined position as shown in FIG. 12C. By using the protective layer 15 in which the first groove 27 is formed as a hard mask, each layer forming the light-emitting element 13 is etched (grooving process). During the grooving process, the first groove 27 is formed further downward, and the assistance layer 26 is also etched together with the lower electrode 13A, the organic layer 13B, and the first upper electrode 13D forming the light-emitting element 13. At the time of etching the assistance layer 26, deposit is generated and attached to the side edge surface of the lower electrode 13A, the organic layer 13B and the first upper electrode 13D to form the sidewall protective film 25 (FIG. 12D). In this way, a state in which the sidewall protective film 25 is formed along the inner wall of the first groove 27 is formed.

After the grooving process, the same process as in the method of manufacturing the display device according to the second embodiment is performed. That is, the process of forming the isolation film 21 in the first groove 27, the process of forming the second groove 23 in a predetermined region around the isolation film 21 from the protective layer 15 to the position of the first upper electrode 13D, and the process of forming the second upper electrode 13E in the second groove 23 are performed. After formation of the second upper electrode 13E, the color filter 17, the filled resin layer 18, and the counter substrate 19 are laminated. Accordingly, the display device 10C according to the third embodiment is obtained.

### 3-3 Operations and Effects

According to the display device according to the third embodiment, the sidewall protective film is formed to cover the side edge surface of the organic layer. The sidewall protective film is a deposit-forming film formed during etching processing in the process (first grooving process) prior to formation of the isolation film. Therefore, even when the isolation film is formed after the first grooving processing, the side edge surface of the organic layer is prevented from being exposed to the external environment (under a low-vacuum environment), and thus characteristics of the organic layer can be improved.

### 3-4 Modified Examples

### Modified Example 1

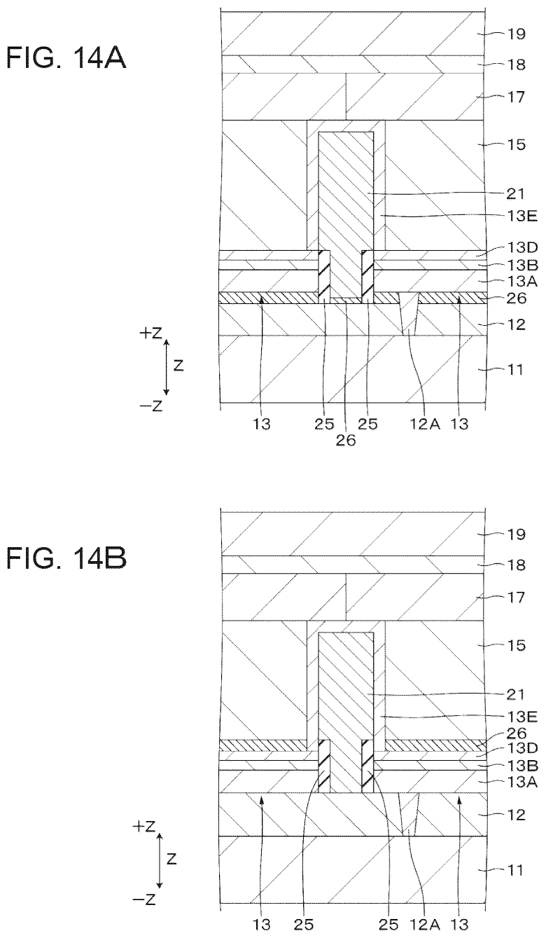

The examples of FIG. 12A to FIG. 12D show the display device when the assistance layer 26 does not remain inside the first groove 27 during the grooving process. That is, in the display device 10C shown in FIG. 11 obtained in this case, the sidewall protective film 25 is not provided on the lower end surface of the isolation film 21. The display device according to the third embodiment is not limited thereto, and the sidewall protective film 25 may be provided on the lower end surface of the isolation film 21, as shown in FIG. 14A. This can be realized by leaving the assistance layer 26 in the first groove 27 during the first grooving process.

### Modified Example 2

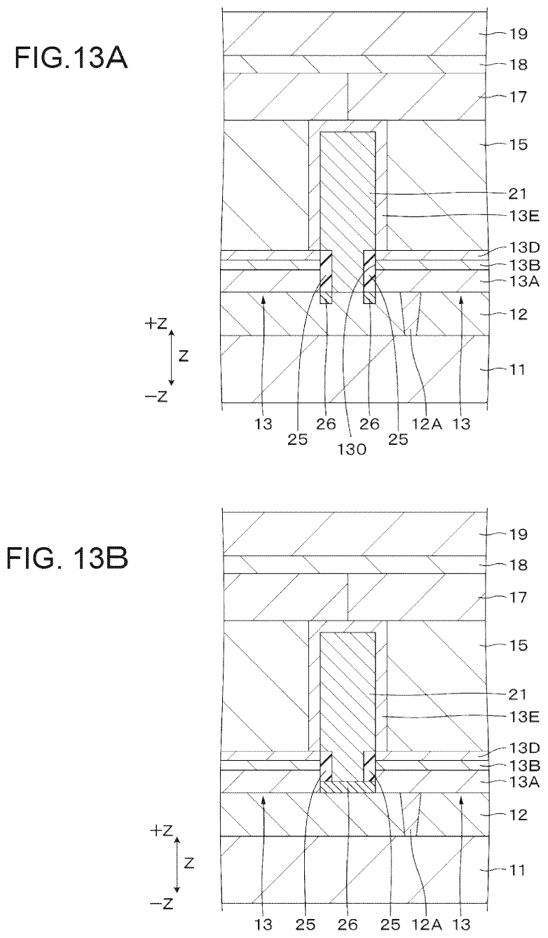

Although a case where the assistance layer 26 is formed all over the lower side of the lower electrode 13A has been described in the example of FIG. 11, the assistance layer 26 may be limitedly formed in a predetermined region between sub-pixels, as shown in FIG. 13A. In the example of FIG. 13A, the assistance layer 26 is formed at a position corresponding to the side edge surface 130 of the light-emitting element 13 when the thickness direction of the light-emitting element 13 is a sight direction, and at a position below the lower electrode 13A. In addition, the sidewall protective film 25 extends upward from the assistance layer 26.

### Modified Example 3

Although a case where the assistance layer 26 is formed below the lower electrode 13A has been described in the example of FIG. 11, the assistance layer 26 may be formed in at the same position as the lower electrode 13A in the vertical direction, as shown in FIG. 13B. In this case, in the example of FIG. 13B, the side edge surface of the lower electrode 13A faces the end surface of the assistance layer 26, the sidewall protective film 25 extends upward from the end edge of the assistance layer 26, and the side edge surface of the organic layer 13B is covered with the sidewall protective film 25.

### Modified Example 4

In the display device 10C according to the third embodiment, the assistance layer 26 may be interposed between the first upper electrode 13D and the protective layer 15, as shown in FIG. 14B.

Such a display device 10C can be manufactured, for example, as follows.

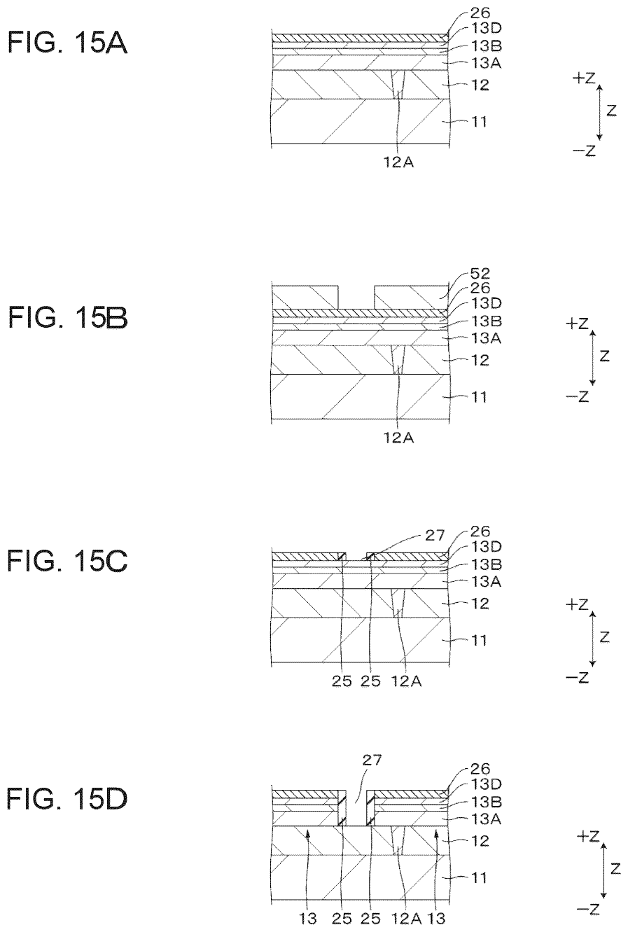

First, the lower electrode 13A, the organic layer 13B, and the first upper electrode 13D are formed on the surface of the substrate 11 in the same manner as in the method of manufacturing the display device according to the second embodiment. Next, the assistance layer 26 is formed on the first upper electrode 13D (FIG. 15A). Further, a resist 52 is provided on the assistance layer 26 (FIG. 15B), and the first groove 27 is formed in the assistance layer 26 at a predetermined position corresponding to the layout of pixels such as sub-pixels using photolithography technology and etching technology. At this time, deposit adheres to the inner wall of the first groove 27 (FIG. 15C). A grooving process is performed through photolithography technology, etching technology, and the like using the assistance layer 26 in which the first groove 27 is formed as a hard mask. In this grooving process, the lower electrode 13A, the organic layer 13B, and the first upper electrode 13D forming the light-emitting element 13 are etched, and the first groove 27 is formed further downward. As the depth of the first groove 27 increases, the deposit derived from the assistance layer 26 also adheres to the side edge surfaces of the lower electrode 13A, the organic layer 13B, and the first upper electrode 13D to form the sidewall protective film 25 (FIG. 15D). In this way, a state in which the sidewall protective film 25 is formed in the first groove 27 is formed.

Next, the isolation film 21 is formed inside the first groove 27 through a method such as a CVD method or a coating method. When the material for forming the isolation film is laminated outside the first groove 27, the material laminated outside the first groove 27 is removed by a CMP method or an etch-back method.

Furthermore, the protective layer 15 is formed all over the surface side of the assistance layer 26. A process of forming a groove in the protective layer 15 at a position corresponding to the first groove 27 is performed on the protective layer 15. Further, the isolation film 21 is formed inside the groove formed in the protective layer 15 through a method such as a CVD method or a coating method. Accordingly, the isolation film 21 is formed in the thickness direction of the light-emitting element 13 from the surface position of the protective layer 15 to the position of the lower electrode 13A. Thereafter, the display device can be obtained in the same manner as the method of manufacturing the display device according to the above-described second embodiment. That is, the process of forming the second groove 23 from the protective layer 15 to the position of the first upper electrode 13D in a predetermined region around the isolation film 21, and the process of forming the second upper electrode 13E in the second groove 23 are carried out. After formation of the second upper electrode 13E, the color filter 17, the filled resin layer 18, and the counter substrate 19 are laminated. Accordingly, the display device 10C is obtained.

Although the sidewall protective film 25 shown in FIG. 14B is formed to have a uniform thickness, this is not limited to a case where the sidewall protective film 25 has a uniform thickness. For example, as shown in FIG. 16B, the sidewall protective film 25 may be formed such that the thickness gradually decreases with increasing distance from the vicinity of an assistance layer 26, which will be described later.

### 4 Fourth Embodiment

With respect to a display device according to a fourth embodiment of the present disclosure, an example of a case in which the display device is an organic EL display device as in the first embodiment will be described.

### 4-1. Configuration of Display Device

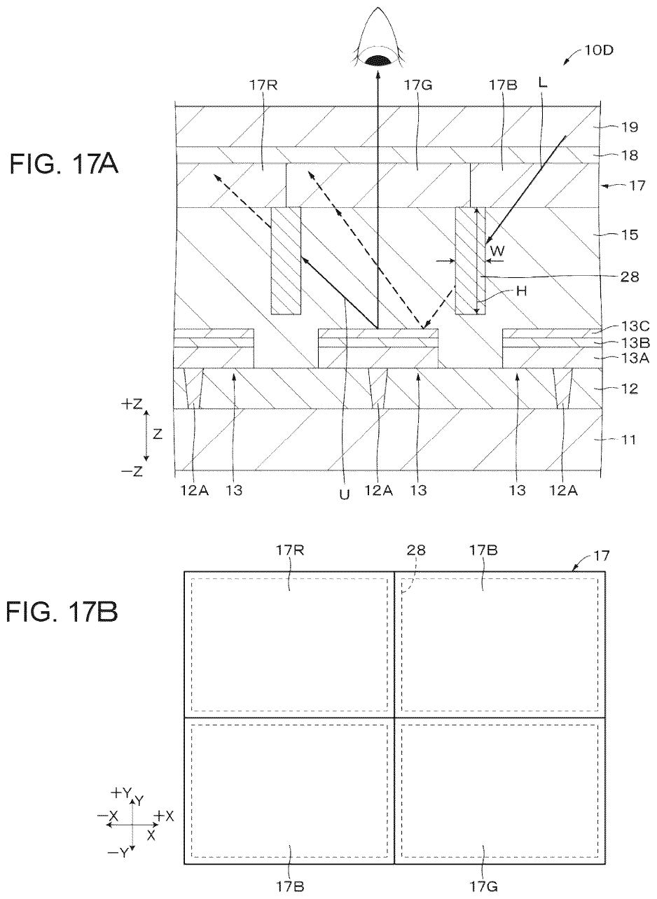

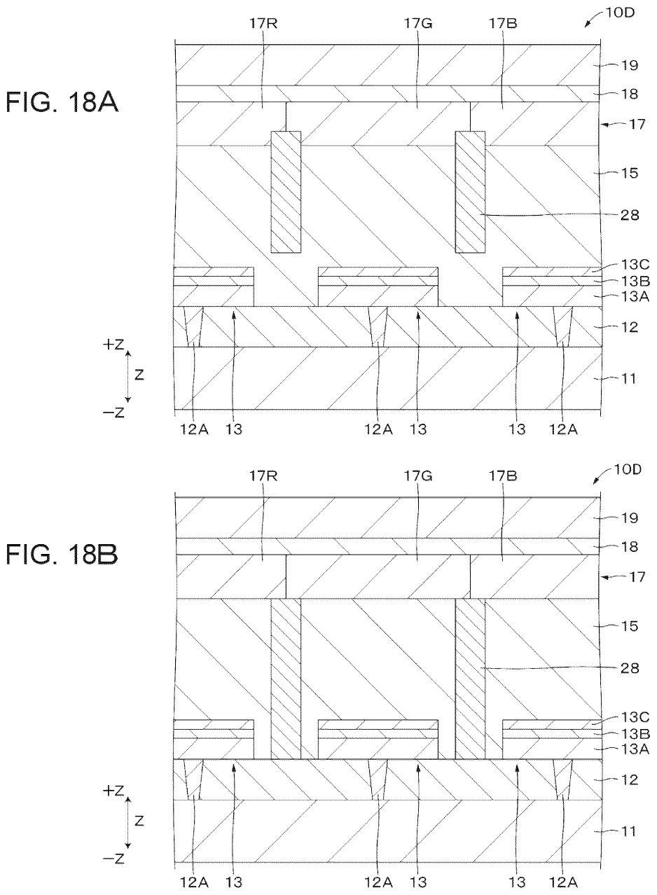

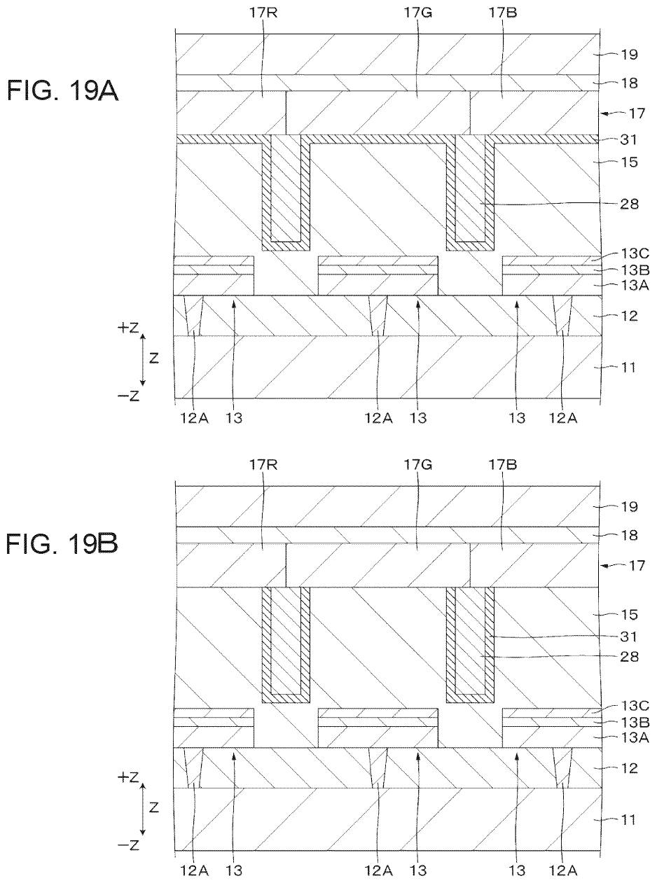

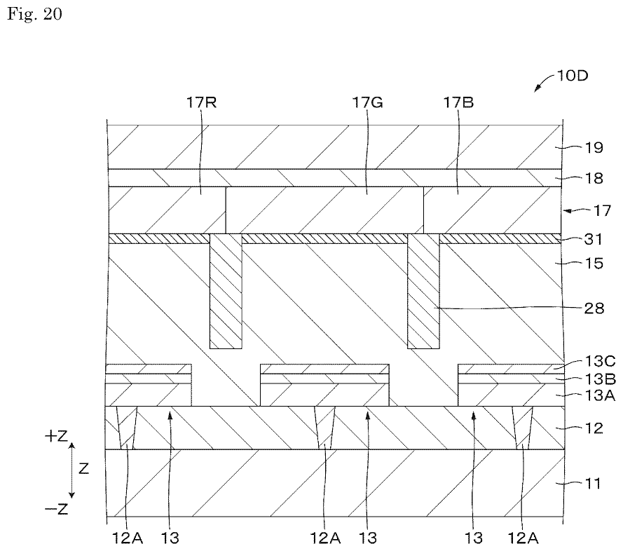

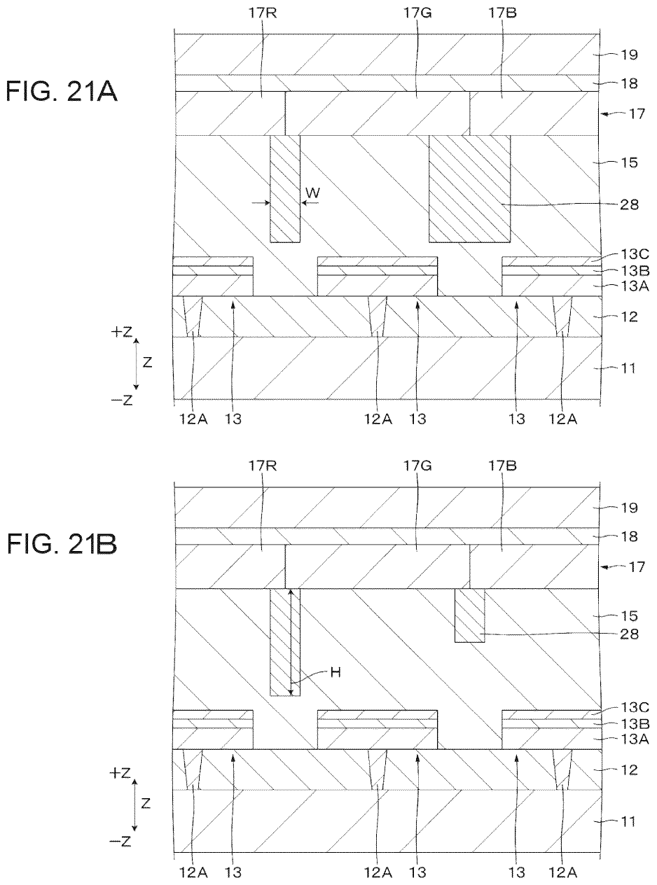

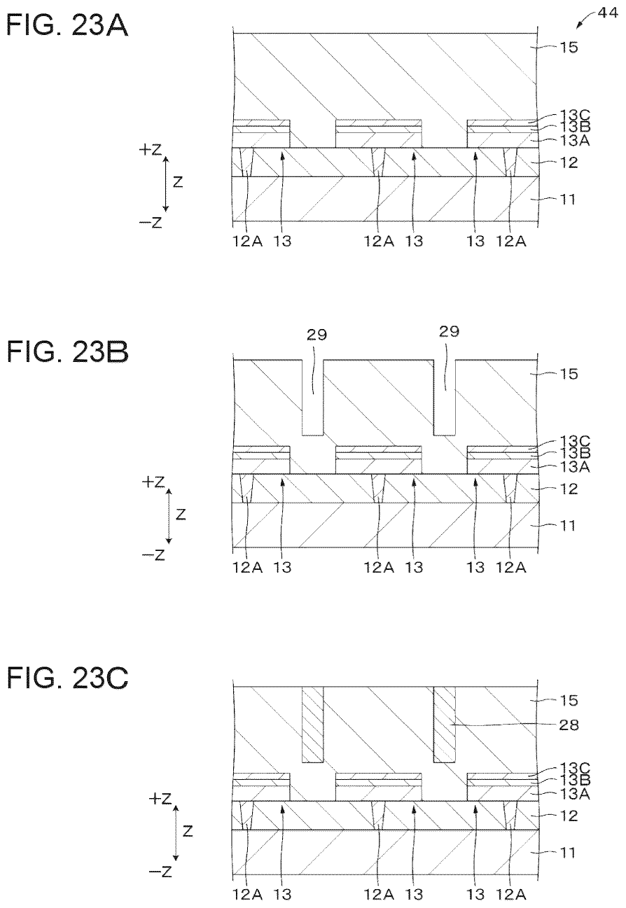

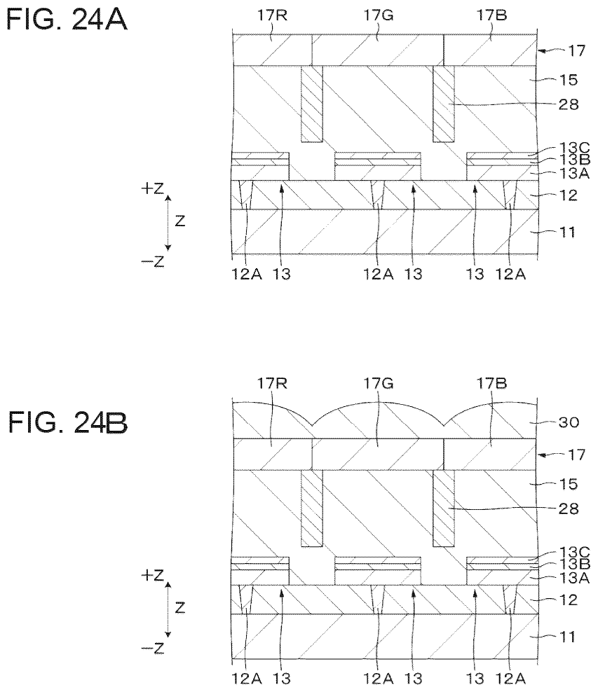

FIG. 17A and FIG. 17B are cross-sectional views showing a configuration example of an organic EL display device (display device 10D) according to an example of the fourth embodiment. The display device 10D is a top emission type display device. The display device 10D includes a substrate 11, an insulating layer 12, a plurality of light-emitting elements 13, a protective layer 15, a light absorption layer 28, and a color filter 17. In the example of the display device according to the fourth embodiment shown in FIG. 17, description of an insulating layer corresponding to the insulating layer 14 in the first embodiment is omitted for convenience of explanation. The same applies to FIG. 18A, FIG. 18B, FIG. 19A, FIG. 19B, FIG. 20, FIG. 21A, FIG. 21B, FIG. 23A, FIG. 23B, FIG. 23B, FIG. 24A, and FIG. 24B. As shown in FIG. 18B, when adjacent light-emitting elements 13 are isolated by the light absorption layer 28, the insulating layer corresponding to the insulating layer 14 may be omitted as in the case of the insulating layer 14 in the first embodiment.

The substrate 11, the insulating layer 12, the protective layer 15 serving as an upper surface protective layer, and the color filter 17 are the same as those in the first embodiment. As described in the first embodiment, a plurality of color filters 17 are provided according to the types of sub-pixels. In the following description of an example of the display device according to the fourth embodiment, a case in which the display device 10D includes a red filter 17R, a green filter 17G, and a blue filter 17B as the color filters 17, as shown in FIG. 17 and the like, will be described. The red filter 17R, the green filter 17G, and the blue filter 17B are provided facing a light-emitting element 13 for a red sub-pixel, a light-emitting element 13 for a green sub-pixel, and a light-emitting element 13 for a blue sub-pixel, respectively, and a gap or a boundary between adjacent color filters 17 is located in a gap between adjacent light-emitting elements 13 in a planar view of the display device 10D (in a planar view of the light-emitting elements).

### Light Absorption Layer

As shown in FIG. 17B, the light absorption layer 28 is formed in a gap or a boundary between adjacent color filters 17 in a planar view of the display device 10D (in a planar view of the light-emitting elements 13). FIG. 17B is a diagram illustrating the positional relationship between the color filter 17 and the light absorption layer 28. The light absorption layer 28 is formed at a position between the color filter 17 and the lower electrode 13A in the thickness direction of the light-emitting element 13. The light absorption layer 28 has a shape extending in a direction (downward) toward the substrate 11 from the color filter 17 and is formed in a shape in which a length H in a direction along the depth direction of the follow color filter 17 is greater than a width length W (width W) in a direction along the in-plane direction (XY plane direction) of the color filter 17 (H>W).

In the example of FIG. 17A, the lower end of the light absorption layer 28 is positioned above the light-emitting element 13. In this case, it is possible to curb incident light L of obliquely incident external light from propagating across the sub-pixels.

A black color filter, a complementary color filter, a non-adjacent color filter, an absorption film, or the like can be used as the light absorption layer 28. As a black color filter, a color filter using carbon, titanium black, or the like as a coloring material can be exemplified. As a complementary color filter, a color filter using a coloring material complementary to the color of the color filter forming the base end of the light absorption layer 28 can be exemplified. As a non-adjacent color filter, a color filter corresponding to a color type other than color types of adjacent color filters serving as the base end of the light absorption layer 28 can be exemplified when the color types of the adjacent color filters are different. Specifically, when the color filter 17 includes the red filter 17R, the green filter 17G, and the blue filter 17B, and the light absorption layer 28 is located at the boundary between the green filter 17G and the red filter 17R, for example, the blue filter 17B may be used as the light absorption layer 28.

Further, an organic material film, an inorganic material film, and the like can be exemplified as the absorption film. A resin film containing a black pigment (for example, carbon black) is desirable as an organic material film. A metal oxide film, a metal single film, or the like is desirable as an inorganic material film, and a metal oxide film is particularly desirable from the viewpoint of excellent light absorption.

### 4-2 Method of Manufacturing Display Device

A method of manufacturing the display device according to the fourth embodiment can be implemented, for example, as described below. An example of a case of manufacturing the display device shown in FIG. 17A and FIG. 17B will be described.

First, the insulating layer 12, the lower electrode 13A, the organic layer 13B, the upper electrode 13C, and the protective layer 15 are laminated on the first surface of the substrate 11 on which the insulating layer 12 is formed to form a first laminate 44 as in the method of manufacturing the display device according to the first embodiment (FIG. 23A). If an insulating layer for isolating the lower electrode 13A for each sub-pixel is provided, this insulating layer is also formed

Next, grooving is performed on the first laminate 44 according to the layout of sub-pixels, for example, using photolithography technology and etching technology, to form a groove 29 to a predetermined depth (FIG. 23B). In the example shown in FIG. 23B, the groove 29 is formed to a depth reaching a predetermined position in the protective layer 15.

Then, a process of forming the light absorption layer 28 in the groove 29 by a method such as a CVD method or a coating method is performed.

After the light absorption layer 28 is formed, the color filter 17 is formed on the surface side of the protective layer 15 by photolithography, for example (FIG. 24A). Accordingly, the color filter 17 is of an on-chip type. A lens 30 may be formed on the surface of the color filter 17 (FIG. 24B). The lens 30 can be formed by applying an on-chip microlens (OCL) formation method using a melting method, an etch-back method, or the like. In this manner, the display device 10D shown in FIG. 17A and FIG. 17B are obtained.

### 4-3 Operations and Effects

In the display device, external light may be obliquely incident and reflected by the lower electrode to form reflected light, and the reflected light may be output to the outside. In this case, if the incident light or the reflected light of the obliquely incident external light propagates across the sub-pixels, and sub-pixels through which the light has passed when it is incident are different from sub-pixels through which the light passes after being reflected by an electrode layer, color mixing or mixture of light occurs in sub-pixels through which the incident light or the reflected light passes, which may reduce the contrast of the display device.

In this regard, according to the display device 10D according to the fourth embodiment, since the light absorption layer 28 extends from the color filter 17 toward the protective layer 15 as shown in FIG. 17A, incident light L of obliquely incident external light is absorbed by the light absorption layer 28, and thus light leakage to adjacent sub-pixels can be curbed. Therefore, the incident light or the reflected light of the obliquely incident external light is less likely to propagate across the sub-pixels, and thus a display device with excellent contrast can be obtained.

Further, according to the display device according to the fourth embodiment, regarding light U from the light-emitting element, light leakage to adjacent sub-pixels is also curbed in the same manner as that for the incident light L of obliquely incident external light, and thus it is possible to curb color mixing or mixture of light between sub-pixels.

### 4-4 Modified Examples

### Modified Example 1

The length of the light absorption layer 28 in the vertical direction is not limited to the example in FIG. 17A. As shown in FIG. 18B, the light absorption layer 28 may extend to a region between adjacent light-emitting elements 13 with the position of the boundary between adjacent color filters 17 as the base end. Further, in that case, the front end of the light absorption layer 28 may enter the insulating layer 12. In the example of FIG. 18B, the light absorption layer 28 isolates adjacent light-emitting elements 13 and thus can function as an element isolation wall.

### Modified Example 2

The light absorption layer 28 is not limited to the example shown in FIG. 17A and may be formed such that the upper end of the light absorption layer 28 is positioned inside the color filter 17, for example, as shown in FIG. 18A. In this case, since the light absorption layer 28 extends to the inside of the color filter 17, light from the light-emitting element 13 is curbed from leaking to adjacent sub-pixels at the position of the color filter 17, and thus the color mixing and mixture of light can be curbed.

### Modified Example 3

As shown in FIG. 19B, an adhesion layer 31 may be formed on the surface of the light absorption layer 28. As shown in FIG. 20, the adhesion layer 31 may be formed between the protective layer 15 and the color filter 17. Further, as shown in FIG. 19A, the adhesion layer 31 may be formed between the protective layer 15 and the color filter 17 and on the surface of the light absorption layer 28.

As the adhesion layer 31, an organic resin or the like can be exemplified. As an organic resin, acrylic resin can be exemplified. Since the adhesion layer 31 is formed in the display device according to the fourth embodiment, incident light and reflected light of obliquely incident external light can also be absorbed by the adhesion layer 31, and thus the amount of light propagated across the sub-pixels can be reduced.

### Modified Example 4

At least one set of combinations of light absorption layers 28 having different widths W may be present for the widths W of light absorption layers 28 formed at different positions when the thickness direction of the color filter 17 is a sight direction. For example, with respect to a combination of adjacent light absorption layers 28 as shown in FIG. 21A, the adjacent light absorption layers 28 may have different widths W. By diversifying the width of the light absorption layer 28, the absorption efficiency of incident light and reflected light of obliquely incident external light can be set to a value corresponding to the sub-pixel.

### Modified Example 5

At least one combination of light absorption layers 28 having different lengths may be present for the lengths H of light absorption layers 28 formed at different positions when the thickness direction of the color filter 17 is a sight direction. For example, with respect to a combination of adjacent light absorption layers 28 as shown in FIG. 21B, the adjacent light absorption layers 28 may have different lengths. By diversifying the length of the light absorption layer 28, the absorption efficiency of incident light and reflected light of obliquely incident external light can be set to a value corresponding to the sub-pixel.

### Modified Example 6

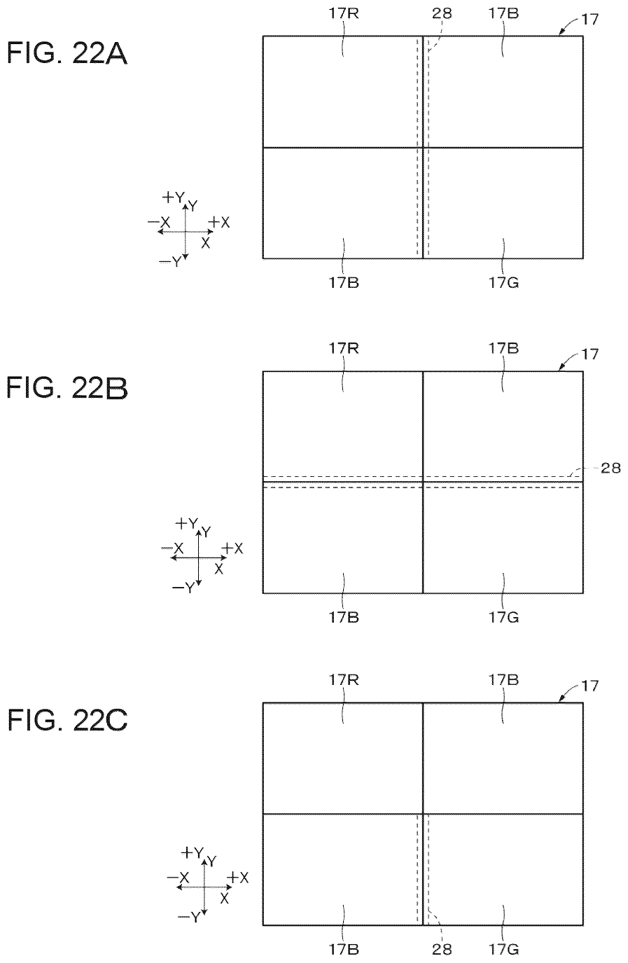

With respect to a region where the light absorption layer is provided when the thickness direction of the color filters 17 is a sight direction, the light absorption layer 28 is disposed between adjacent color filters 17 or across the boundary between adjacent color filters 17 in the example of FIG. 17B. The display device according to the fourth embodiment is not limited thereto, and the light absorption layer 28 may be disposed between adjacent color filters 17 or at a part of the boundary between adjacent color filters 17, as shown in FIG. 22A, FIG. 22B, and FIG. 22C. FIG. 22A, FIG. 22B, and FIG. 22C are diagrams for describing the positional relationship between the color filter 17 and the light absorption layer 28. FIG. 22A shows an example in which the light absorption layer is disposed between color filters 17 adjacent in the X direction (between the blue filter 17B and the green filter 17G and between the red filter 17R and the blue filter 17B). FIG. 22B shows an example in which the light absorption layer is disposed between color filters 17 adjacent in the Y direction (between the red filter 17R and the blue filter 17B and between the blue filter 17B and the green filter 17G). FIG. 22C shows an example in which the light absorption layer 28 is disposed in half the region where the light absorption layer 28 is disposed in FIG. 22A.

Next, as application examples of the display device, examples of an electronic apparatus using the display device according to any one of the first to fourth embodiments will be described.

### 5. Application Examples

### Electronic Apparatus

The display devices 10A, 10B, 10C, and 10D according to the embodiments described above may be provided in various electronic apparatuses. In particular, it is desirable to provide the display devices in electronic apparatuses which require a high resolution and is used in a magnified manner near the eyes, such as a video camera, an electronic viewfinder of a single-lens reflex camera, a head-mounted display, and the like.

### Specific Example 1

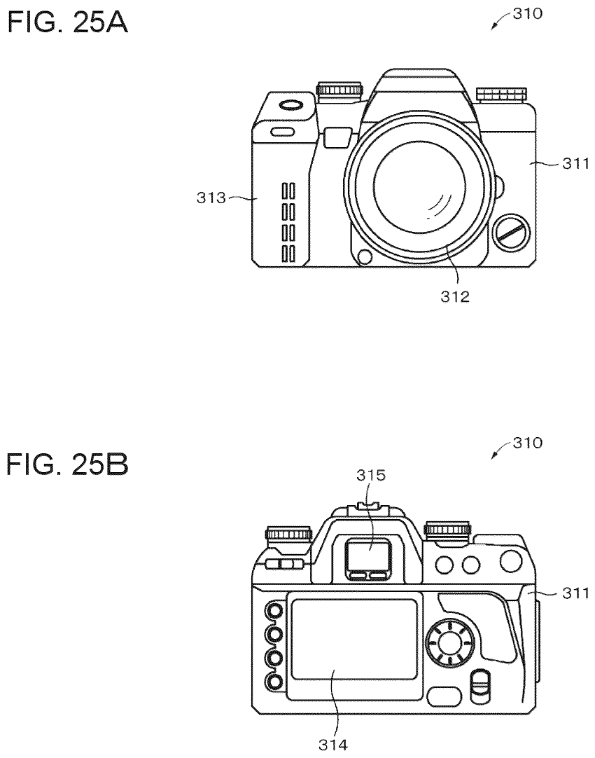

FIG. 25A is a front view showing an example of the appearance of a digital still camera 310. FIG. 25B is a rear view showing an example of the appearance of the digital still camera 310. This digital still camera 310 is of an interchangeable single-lens reflex type and has an interchangeable photographing lens unit (interchangeable lens) 312 in approximately the center of the front of a camera main body (camera body) 311 and a grip portion 313 for being gripped by a photographer on the left side of the front.

A monitor 314 is provided at a position shifted to the left from the center of the rear surface of the camera body 311. An electronic viewfinder (eyepiece window) 315 is provided above the monitor 314. A photographer can visually recognize an optical image of a subject guided by the photographing lens unit 312 and determine a composition by looking through the electronic viewfinder 315. As the electronic viewfinder 315, any one of the display devices 10A, 10B, 10C, and 10D according to the first to fourth embodiments and modified examples can be used.

### Specific Example 2

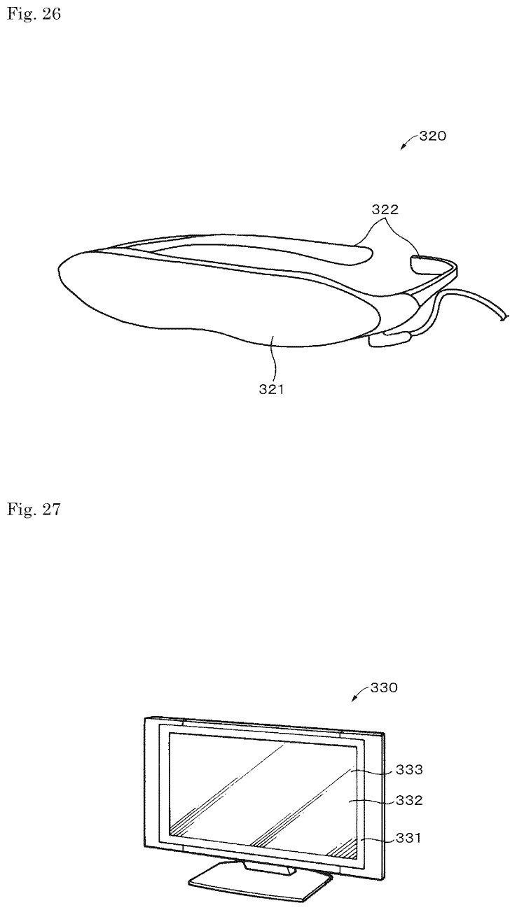

FIG. 26 is a perspective view showing an example of the appearance of a head-mounted display 320. The head-mounted display 320 has, for example, ear hooks 322 on both sides of an eyeglass-shaped display unit 321 to be worn on the head of a user. As the display unit 321, any one of the display devices 10A, 10B, 10C, and 10D according to the first to fourth embodiments and modified examples can be used.

### Specific Example 3

FIG. 27 is a perspective view showing an example of the appearance of a television device 330. This television device 330 has, for example, a video display screen part 331 including a front panel 332 and a filter glass 333, and this video display screen part 331 is composed of any one of the display devices 10A, 10B, 10C, and 10D according to the above-described first to fourth embodiments and modified examples.

Although the first to fourth embodiments of the present disclosure and modified examples thereof have been specifically described above, the present disclosure is not limited to the above-described first to fourth embodiments and modified examples thereof, and various modifications based on the technical idea of the present disclosure are possible.

For example, the configurations, methods, processes, shapes, materials, numerical values, and the like given in the above-described first to fourth embodiments and modified examples thereof are merely examples, and different configurations, methods, processes, shapes, materials, numerical values, and the like may be used if necessary.

In addition, the configurations, methods, processes, shapes, materials, numerical values, and the like in the above-described first to fourth embodiments and modified examples thereof described above can be combined with each other without departing from the gist of the present disclosure.

Unless otherwise specified, the materials exemplified in the above-described first to fourth embodiments and the modified examples thereof can be used alone or two or more thereof in combination.

In addition, the present disclosure may adopt the following constitutions.
(1) A display device including a plurality of light-emitting elements in which a lower electrode, an organic layer and an upper electrode are laminated in this order on a substrate,
an upper surface protective layer laminated on an upper surface side of the light-emitting elements and covering the upper electrode, and
an element isolation wall disposed between adjacent light-emitting elements and covering side edge surfaces of the light-emitting elements,
wherein
the element isolation wall extends from the light-emitting elements toward the upper surface protective layer in a thickness direction of the light-emitting elements.
(2) The display device according to the (1), wherein a low refractive index portion having a refractive index lower than a refractive index of the element isolation wall is formed in the element isolation wall.
(3) The display device according to the (2), including an insulating layer including a plurality of wires between the substrate and the plurality of light-emitting elements,
wherein the plurality of wires are arranged adjacently in an in-plane direction of the substrate,
a lower end of the low refractive index portion is positioned between adjacent wires or below the region between the adjacent wires, and
an upper end of the low refractive index portion is positioned above an interface between each of the light-emitting elements and the upper surface protective layer.
(4) The display device according to the (2) or (3), wherein the element isolation wall is formed of a material having a step coverage value of less than 1.
(5) The display device according to any one of the (2) to (4), wherein the element isolation wall has a lower refractive index value than the upper surface protective layer.
(6) The display device according to any one of the (2) to (5), wherein a cross-sectional shape of the low refractive index portion is polygonal.
(7) The display device according to any one of the (2) to (6), wherein the low refractive index portion has a bottom surface portion and a sidewall portion standing up from the bottom surface portion, and
a taper angle formed between the bottom surface portion and the sidewall portion is 90° or less.
(8) The display device according to the (1), wherein the upper electrode is first upper electrodes isolated from each other and facing the organic layer,
a second upper electrode connecting the adjacent first upper electrodes is provided, and
the second upper electrode is disposed along the surface of the element isolation wall.
(9) The display device according to the (8), wherein the element isolation wall extends upward from the first upper electrodes.
(10) The display device according to the (9), wherein the second upper electrode extends to an extending end of the element isolation wall with a position where the first upper electrodes and the element isolation wall face each other as a base end, and spreads along the surface of the upper surface protective layer from the extending end of the element isolation wall.
(11) The display device according to any one of the (8) to (10), wherein a lower end of the element isolation wall is positioned below a lower end of the lower electrode or below the lower electrode.
(12) The display device according to any one of the (8) to (11), wherein a length of the element isolation wall in the thickness direction of the light-emitting elements is greater than a sum of a thickness of the lower electrode, a thickness of the organic layer, and a thickness of the first upper electrodes.
(13) The display device according to any one of the (8) to (12), wherein a reflectance of the second upper electrode is higher than a reflectance of the first upper electrodes.
(14) The display device according to any one of the (8) to (13), wherein a refractive index of the element isolation wall is less than a refractive index of the second upper electrode.
(15) The display device according to any one of the (8) to (14), wherein a sidewall protective film is interposed between a side edge surface of the organic layer and the element isolation wall.
(16) The display device according to the (15), wherein the sidewall protective film contains by-products generated during etching processing.
(17) The display device according to the (15) or (16), wherein an assistance layer is interposed between the lower electrode and the substrate or between the upper electrode and the upper surface protective layer,
the sidewall protective film extends with the assistance layer as a base end, and
the sidewall protective film contains at least one element forming the assistance layer.
(18) A display device including a plurality of light-emitting elements in which a lower electrode, an organic layer, and an upper electrode are laminated in this order on a substrate, wherein
an upper surface protective layer covering the upper electrode is laminated on an upper surface side of the light-emitting elements,
an element isolation wall is formed at least one of a region between adjacent light-emitting elements and a region between adjacent upper surface protective layers, and
a low refractive index portion is formed in the element isolation wall.
(19) A display device including a plurality of light-emitting elements in which a lower electrode, an organic layer, and a first upper electrode are laminated in this order on a substrate in a state in which the light-emitting elements are isolated for each sub-pixel, wherein
an element isolation wall is formed between adjacent light-emitting elements to cover side edge surfaces of the light-emitting elements,
the element isolation wall extends upward from the first upper electrode toward the upper surface protective layer from the light-emitting elements in a thickness direction of the light-emitting element, and
a second upper electrode connecting adjacent first upper electrodes is formed along the surface of the element isolation wall.
(20) The display device according to the (19), wherein a surface of a portion of the element isolation wall extending upward beyond the first upper electrode is covered with the second upper electrode.
(21) The display device according to the (19) or (20), wherein a sidewall protective film is interposed between a side edge surface of the organic layer and the element isolation wall.
(22) A display device including a plurality of light-emitting elements in which a lower electrode, an organic layer, and an upper electrode are laminated in this order on a substrate, wherein
a color filter is provided on the upper surface side of each of the light-emitting elements,
a light absorption layer is provided between the color filter and the lower electrode, and
a length of the light absorption layer in a direction along a thickness direction of the color filter is greater than a width of the light absorption layer in a direction along an in-plane direction of the color filter.
(23) The display device according to the (22), wherein the light absorption layer is a black color filter.
(24) The display device according to the (22) or (23), wherein the light absorption layer is a complementary color filter corresponding to a complementary color of the color filter positioned at a base end of the light absorption layer.
(25) The display device according to the (22) or (23), wherein the light absorption layer is a non-adjacent color filter corresponding to a color different from a color of the color filter positioned at the base end of the light absorption layer.
(26) The display device according to the (22) or (23), wherein the light absorption layer is an inorganic material film.
(27) The display device according to any one of the (22) to (26), wherein a part of the light absorption layer enters the inside of the color filter.
(28) The display device according to any one of the (22) to (27), wherein at least one of the light absorption layer and the color filter is provided with an adhesion layer formed of a resin material.
(29) The display device according to any one of the (22) to (28), wherein, when widths of light absorption layers formed at different positions with the thickness direction of the color filter as a sight direction are compared, at least one combination of the light absorption layers having different widths is present.
(30) The display device according to any one of the (22) to (29), wherein, when lengths of light absorption layers formed at different positions with the thickness direction of the color filter as a sight direction are compared, at least one combination of the light absorption layers having different lengths is present.
(31) An electronic apparatus including the display device according to any one of the (1) to (30).
(32) A method of manufacturing a display device, including a process of forming a first laminate in which a lower electrode, an organic layer, a first upper electrode, and an upper surface protective layer are laminated in this order on a substrate,
a process of forming a first groove to a predetermined depth from the upper surface protective layer at a predetermined position in the first laminate,
a process of forming a second laminate by forming an element isolation wall in the first groove,
a process of forming a second groove from the upper surface protective layer to a position of the first upper electrode in a predetermined region around the element isolation wall in the second laminate, and
a process of forming a second upper electrode in the second groove.
(33) A method of manufacturing a display device, including a process of forming a first laminate in which a laminate obtained by laminating a lower electrode, an organic layer, a first upper electrode, and an upper surface protective layer in this order and an assistance layer are provided on a substrate,
a process of forming a first groove to a predetermined depth at a predetermined position in the first laminate through etching processing, and forming a sidewall protective film having the assistance layer as a base end along an inner wall of the first groove with the etching processing,
a process of forming a second laminate by forming an element isolation wall in the first groove,
a process of forming a second groove from the upper surface protective layer to a position of the first upper electrode in a predetermined region around the element isolation wall in the second laminate, and
a process of forming a second upper electrode in the second groove.

### REFERENCE SIGNS LIST

10A, 10B, 10C, 10D Display device
11 Substrate
12 Insulating layer
13A Lower electrode
13B Organic layer
13C Upper electrode
13D First upper electrode
13E Second upper electrode
14 Insulating layer
15 Protective layer
16 Protective layer
16A First protective portion
16B Second protective portion
17 Color filter
18 Filled resin layer
19 Counter substrate
20 Void
21 Isolation film
25 Sidewall protective film
28 Light absorption layer
310 Digital still camera (electronic apparatus)
320 Head-mounted display (electronic apparatus)
330 Television device (electronic apparatus)

1. A display device comprising:
an anode electrode;
a cathode electrode;
an organic layer between the anode electrode and the cathode electrode;
a first insulating layer covering at least a portion of a side surface of the anode electrode and at least a portion of a top surface of the anode electrode; and
a cavity between the anode electrode and another anode electrode adjacent to the anode electrode,
wherein a first distance between an uppermost point and a lowermost point of a first side surface of the first insulating layer facing the cavity is shorter than a second distance between an uppermost point and a lowermost point of the cavity in a cross-sectional view.

2. The display device according to claim 1, wherein the first side surface of the first insulating layer is substantially perpendicular to a substrate in the cross-sectional view.

3. The display device according to claim 1, wherein the first insulating layer is between a substrate and the cathode electrode.

4. The display device according to claim 1, wherein the first insulating layer is in contact with the anode electrode.

5. The display device according to claim 1, further comprising a second insulating layer below the first insulating layer.

6. The display device according to claim 5, wherein the lowermost point of the cavity and a portion of the second insulating layer are at a same height from a substrate in the cross-sectional view.

7. The display device according to claim 1, further comprising a protection layer between the first insulating layer and the cavity.

8. The display device according to claim 7, wherein the first side surface of the first insulating layer is in contact with the protection layer.

9. The display device according to claim 1, wherein the side surface of the anode electrode is tapered in the cross-sectional view.

10. The display device according to claim 1, wherein the uppermost point of the first side surface of the first insulating layer and the uppermost point of the cavity is farther from a substrate, and the lowermost point of the first side surface of the first insulating layer and the lowermost point of the cavity is closer to the substrate in the cross-sectional view.

11. The display device according to claim 1, wherein the uppermost point of the cavity is above the cathode electrode in the cross-sectional view.

12. The display device according to claim 1, wherein the lowermost point of the cavity is below the anode electrode in the cross-sectional view.

13. The display device according to claim 1, wherein the cavity is filled by a low refractive index material.

14. The display device according to claim 1, wherein the cathode electrode is separated from other cathode electrodes for respective light emitting elements.

15. The display device according to claim 1, further comprising a third electrode disposed along a surface of the cavity in the cross-sectional view and connecting adjacent cathode electrodes.

16. An electronic apparatus comprising the display device according to claim 1.
